(19) United States
(12) Patent Application Publication
(10) Pub. No.: US 2009/0047418 A1
(43) Pub. Date: Feb. 19, 2009

(54) FILM-FORMING METHOD, AND FILM FORMING DEVICE

(75) Inventors: Hirotsuna MIURA, Fujimi (JP); Yoshikazu HAMA, Okaya (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/185,970

(22) Filed: Aug. 5, 2008

(30) Foreign Application Priority Data
Aug. 17, 2007 (JP) 2007-212649
Jul. 14, 2008 (JP) 2008-182379

(51) Int. Cl. C23C 14/54; B05C 11/00

(52) U.S. Cl. 427/10; 118/697

(57) ABSTRACT

A film-forming method includes: a) discharging a liquid including a film material on an object so as to form a liquid film made of the liquid; b) measuring distribution of an optical constant related to a film thickness of a thin film by irradiating the liquid film with light from a first light source so as to detect light from the liquid film; and c) modulating light from a second light source corresponding to the optical constant of the liquid film based on converting data indicating a relation between the optical constant and light wave information of the light from the second light source while irradiating the liquid film with the light from the second light source so as to dry the liquid film to form the thin film on the object.

### BACKGROUND

1. Technical Field

The present invention relates to a film-forming method, and a film-forming device.

2. Related Art

Multi-layered substrates made of low temperature co-fired ceramics (LTCC) are widely used for a substrate of a high frequency module, a substrate of an IC package, and the like due to their excellent high-frequency property and high heat-resistance. As a method for manufacturing a film pattern of a wiring and the like included in the LTCC multi-layered substrates, an inkjet method has attracted attention in order to improve productivity and reduce a cost. The inkjet method uses a droplet discharge head that discharges a liquid material including a wiring material as a droplet. In the method, the droplet discharge head is allowed to discharge a droplet while the droplet discharge head and a substrate are relatively moved in a main scanning direction. A plurality of droplets including the wiring material are sequentially united along the main scanning direction of the substrate so as to form a liquid film having a linear shape and continuing in the main scanning direction. In the inkjet method, the liquid film in such a linear shape is dried so as to form a pattern.

JP-A-2005-152758 discloses a following inkjet method in which a temperature gradient is provided to a surface of a linear liquid film so as to form a high-temperature side end and a low-temperature side end on both sides across a main scanning direction on the film. The liquid film having the temperature gradient forms surface tension distribution on its surface and generates Marangoni convection in an inside thereof. A thermal capillary flow flowing out from the high-temperature side end of the liquid film descends toward a substrate before the flow reaches the low-temperature side end due to the temperature gradient applied to the liquid film. As a result, a wiring material that is not included in a flow path of Marangoni convection is separated out. Due to this wiring material separated out, the spread of the liquid film is pinned. On the other hand, the wiring material is continuously conveyed to the high-temperature side end by the convection, causing difficulty in separating out the wiring material. Therefore, as the drying of the liquid film progresses, the high-temperature side end is constricted toward the low-temperature side end of the liquid film, separating out the wiring material only at the low-temperature side end of the liquid film. As a result, the liquid film forms a wiring pattern having a line width narrower than the film itself.

The inkjet method mentioned above has attracted attention also as a method for forming an orientation film that is to be used for a liquid crystal display, as shown in JP-A-2006-15271, for example. FIGS. 12A and 13A are plan views and FIGS. 12B and 13B are side views schematically showing a film-forming process of an orientation film. In the film-forming of an orientation film, a droplet discharge process in which a droplet D is discharged on a substrate S so as to form a liquid film F0 and a dry process in which a solvent and the like included in the liquid film F0 are evaporated so as to dry the liquid film F0 are conducted.

As shown in FIGS. 12A and 12B, in the droplet discharge process, a surface of the substrate S (hereinafter, referred to as “discharge surface Sa”) is virtually divided into a plurality of discharge regions R extending in a vertical direction in a horizontal direction in a sequential manner. A droplet discharge head H sequentially moves from above a leftmost one of the discharge regions R along an arrow direction so as to discharge a plurality of droplets D including an orientation film material to the whole of the discharge regions R. Thus a partial liquid film F having a strip shape is formed on each of the plurality of discharge regions R. That is, the droplet discharge head H forms the liquid film F0 by multi-scanning. Alternatively, as shown in FIGS. 13A and 13B, a plurality of droplet discharge heads H arranged in a horizontal direction respectively discharge the droplet D on the whole of each of the discharge regions R so as to form the partial liquid film F on each of the plurality of discharge regions R. That is, the plurality of droplet discharge heads H form the liquid film F0 by single-scanning. Each of a plurality of partial liquid films F is united with adjacent partial liquid film F so as to form the liquid film F0 covering the whole of the substrate S.

In a case of film-forming by multi-scanning, landing timings of the droplets D are different from each other at a boundary between the partial liquid films F that are adjacent by a period of one scanning of the droplet discharge head. Further, even in a case of film-forming by single-scanning, landing timings of the droplets D are different from each other at a boundary between the partial liquid films F that are adjacent by a period between scans of the droplet discharge heads H that are formed with a certain distance.

At end parts (both end parts Fe in a horizontal direction, for example) of the partial liquid film F, a surface area per unit volume is large, so that evaporation probability of an evaporation component at the end parts increases and thus a drying speed becomes higher than that at a central part Fc. Therefore, flowage of the orientation film material occurs inside of the liquid material due to its increased viscosity, so that a concentration of the orientation film material becomes locally high at the both end parts Fe of the partial liquid film F. As a result, when the liquid film F0 is dried, difference in film thickness (contrasting density in FIGS. 12A and 13A) is disadvantageously formed at the both end parts Fe of the liquid film F0 after the dry process.

### SUMMARY

An advantage of the present invention is to provide a film-forming method and a film-forming device that are able to improve film thickness controllability of a film to be formed by drying a liquid film.

A film-forming method according to a first aspect of the invention includes: a) discharging a liquid including a film material on an object so as to form a liquid film made of the liquid; b) measuring distribution of an optical constant related to a film thickness of a thin film by irradiating the liquid film with light from a first light source so as to detect light from the liquid film; and c) modulating light from a second light source corresponding to the optical constant of the liquid film based on converting data indicating a relation between the optical constant and light wave information of the light from the second light source while irradiating the liquid film with the light from the second light source so as to dry the liquid film to form the thin film on the object.

According to the film-forming method of the first aspect, the light emitted from the second light source to the liquid film is modulated based on the distribution of the optical constant related to the thickness of the thin film. Therefore, in the film forming method, the light for drying is modulated based on the distribution of the optical constant related to the thickness of the thin film, thereby improving film thickness controllability of the thin film. In addition, measurement of the optical constant related to the thickness of the thin film and drying the liquid film are performed with light. Therefore, the film-forming method can control a drying state and a film shape of the liquid film in higher alignment accuracy.

In the film-forming method, the converting data may correlate the optical constant in a case where a concentration of the film material is high with light with a low intensity, and step c) may include modulating an intensity of the light from the second light source corresponding to a measurement result of the light from the liquid film based on the converting data so as to dry the liquid film.

In the film forming method, a high concentration part of the film material receives respectively low energy. Therefore, the film forming method can decrease evaporation probability of the high concentration part of the film material, thereby controlling evaporation probability of the liquid film so as to be uniform throughout the whole of the liquid film.

In the film-forming method, the converting data may correlate the optical constant in a case where a concentration of the film material is low with light with a high intensity, and step c) may include modulating the intensity of the light from the second light source corresponding to the measurement result of the light from the liquid film based on the converting data so as to dry the liquid film.

According to the film forming method, a low concentration part of the film material receives respectively high energy. Therefore, the film forming method can increase evaporation probability of the low concentration part of the film material, thereby controlling evaporation probability of the liquid film so as to be uniform throughout the whole of the liquid film.

A film-forming method according to a second aspect of the invention includes: d) discharging a liquid including a film material on an object so as to form a liquid film made of the liquid; e) measuring a film shape of the liquid film by irradiating the liquid film with light from a first light source so as to detect light from the liquid film; and f) modulating light from a second light source corresponding to the film shape of the liquid film based on converting data indicating a relation between the film shape and light wave information of the light from the second light source while irradiating the liquid film with the light from the second light source so as to dry the liquid film to form the thin film on the object.

In the film-forming method, step e) may include detecting a position of the light from the liquid film by irradiating the liquid film with the light from the first light source so as to measure the film shape of the liquid film based on a detecting result of the position.

In the film-forming method, step e) may include detecting a focal distance of the first light source with respect to the liquid film by irradiating the liquid film with the light from the first light source so as to measure the film shape of the liquid film based on a detecting result of the focal distance.

In the film-forming method, step e) may include imaging interference light of the liquid film by irradiating the liquid film with the light from the first light source so as to measure the film shape of the liquid film based on an imaging result of the interference light.

According to the film forming method above, distribution of light energy provided to the liquid film is determined by the film shape of the liquid film, that is, distribution of the film thickness. Therefore, the film-forming method above can change a drying state of the liquid film based on the film shape, thereby improving shape controllability of the liquid film, further, film thickness controllability of the film formed by drying the liquid film.

In the film-forming method, the converting data may correlate a thick part of the liquid film with light with a low intensity, and step f) may include modulating an intensity of the light from the second light source corresponding to a measurement result of the light from the liquid film based on the converting data so as to dry the liquid film.

According to the film forming method, the thick part of the film thickness receives low energy. Therefore, the film forming method can decrease evaporation probability of the thick part of the film thickness, thereby controlling evaporation probability of the liquid film so as to be uniform throughout the whole of the liquid film.

In the film-forming method, the converting data may correlate a thin part of the liquid film with light with a high intensity, and step f) may include modulating the intensity of the light from the second light source corresponding to a measurement result of the light from the liquid film based on the converting data so as to dry the liquid film.

According to the film forming method, the thin part of the film thickness receives high energy. Therefore, the film forming method can increase evaporation probability of the thin part of the film thickness, thereby controlling evaporation probability of the liquid film to be uniform throughout the whole of the liquid film.

In the film-forming method, step b) may include imaging interference light of the liquid film by irradiating the liquid film with the light from the first light source while step c) may include modulating the light from the second light source based on only a phase of the interference light.

According to the film-forming method, the light emitted from the second light source to the liquid film is modulated based on the phase of the interference light only. Therefore, the film-forming method can achieve the modulating process of the drying light with a simpler structure, and further, can improve the film thickness controllability of the thin film with a simpler method.

In the film-forming method, step c) may include modulating the light from the second light source based on data in which a random phase is added to the phase of the interference light.

According to the film-forming method, the light emitted from the second light source to the liquid film can suppress energy concentration thereof by adding the random phase. Therefore, in the film-forming method, the light energy for drying is dispersed on the liquid film, thereby improving flatness of the thin film.

In the film-forming method, the light from the second light source may have a wavelength at which the light is absorbed by the object at a higher rate than a rate at which the light is absorbed by the liquid.

According to the film-forming method, the light energy from the second light source is converted into thermal energy by the object, and then provided to the liquid film. Therefore, the liquid film is prevented from locally drying or rapidly drying, more assuredly improving the film thickness controllability of the thin film.

In the film-forming method, step b) and step c) may be alternately repeated.

Therefore, the film-forming method can more assuredly improves the film thickness controllability of the thin film in accordance with the number of times to repeat measurement of the optical constant and the shape of the liquid film.

In the film-forming method, the first light source and the second light source may be served by a single light source.

According to the film-forming method, the single light source is controlled so as to provide light for measurement and light for drying. Therefore, the film-forming method can improve the film thickness controllability of the thin film with a simpler structure.

A film-forming device according to a third aspect of the invention includes: a discharge head discharging a liquid including a film material on an object so as to form a liquid film on the object; a dryer drying the liquid film so as to form a thin film on the object, the dryer including: a first light source; a second light source; a first irradiator irradiating the liquid film with light from the first light source; a detector detecting light from the liquid film so as to measure an optical constant related to a thickness of the thin film; a modulator modulating light from the second light source; a second irradiator irradiating the liquid film with light from the modulator; and a controller controlling the discharge head and the dryer, the controller including: a mode selector selecting a measurement mode and a dry mode; a memory storing converting data indicating a relation between the optical constant and light wave information of the light from the second light source, wherein the controller operates the first irradiator and the detector so as to measure the optical constant related to the thickness of the thin film in the measurement mode, while the controller generates modulating data for modulating the light from the second light source based on the optical constant of the liquid film and the converting data, and outputs light corresponding to the modulating data to the liquid film by operating the modulator with the converting data in the dry mode.

According to the film-forming device, the light from the second light source in the dry mode is modulated based on the optical constant related to the thickness of the thin film. Therefore, in the film-forming device, the drying light is modulated based on the optical constant related to the thickness of the thin film, thereby improving the film thickness controllability of the thin film. In addition, measurement of the optical constant related to the thickness of the thin film and drying the liquid film are conducted with light. Therefore, the film-forming device can control a drying state and a film shape in higher alignment accuracy.

In the film-forming device, the converting data may correlate the optical constant in a case where a concentration of the film material is high with light with a low intensity, and the controller may modulate the light from the second light source based on the converting data in the dry mode.

According to the film forming device, a high concentration part of the film material receives respectively low energy. Therefore, the film forming device can decrease evaporation probability of the high concentration part of the film material, thereby controlling evaporation probability of the liquid film so as to be uniform throughout the whole of the liquid film.

In the film-forming method, the converting data may correlate the optical constant in a case where a concentration of the film material is low with light with a high intensity, and the controller may modulate the light from the second light source based on the converting data in the dry mode.

According to the film forming device, the low concentration part of the film material receives respectively high energy. Therefore, the film forming device can increase evaporation probability of the low concentration part of the film material, thereby controlling evaporation probability of the liquid film so as to be uniform throughout the whole of the liquid film.

A film-forming device according to a fourth aspect of the invention includes: a discharge head discharging a liquid including a film material on an object so as to form a liquid film on the object; a dryer drying the liquid film so as to form a thin film on the object, the dryer including: a first light source; a second light source; a first irradiator irradiating the liquid film with light from the first light source; a detector detecting light from the liquid film so as to measure a film shape of the liquid film; a modulator modulating light from the second light source; and a second irradiator irradiating the liquid film with light from the modulator; and a controller controlling the discharge head and the dryer, the controller including: a mode selector selecting a measurement mode and a dry mode; a memory storing converting data indicating a relation between the film shape and light wave information of the light from the second light source, wherein the controller operates the first irradiator and the detector so as to generate information on the film shape of the liquid film in the measurement mode, while the controller generates modulating data for modulating the light from the second light source based on the film shape of the liquid film and the converting data, and outputs light corresponding to the modulating data to the liquid film by operating the modulator with the modulating data.

In the film-forming device, the controller may calculate a surface coordinate of the liquid film as information on the film shape based on a detecting result from the detector in the measurement mode.

In the film-forming device, the detector may detect a position of the light from the liquid film, while the controller may calculate a surface coordinate of the liquid film as information on the film shape based on the position of the light from the liquid film, the position being detected by the detector, in the measurement mode.

In the film-forming device, the detector may detect a focal position of the first light source with respect to the liquid film, while the controller may calculate a surface coordinate of the liquid film as information on the film shape based on the focal position detected by the detector in the measurement mode.

In the film-forming device, the detector may detect interference light of the liquid film, while the controller may calculate a surface coordinate of the liquid film as information on the film shape based on the interference light detected by the detector.

According to the film forming device above, distribution of light energy provided to the liquid film is determined by the film shape of the liquid film, that is, distribution of the film thickness. Therefore, the film-forming device above can change the drying state of the liquid film based on the shape of the liquid film, thereby improving shape controllability of the liquid film, further, film thickness controllability of the film formed by drying the liquid film.

In the film-forming device, the converting data may correlate a thick part of the liquid film with light with a low intensity.

According to the film forming device, the thick part of the film thickness receives low light energy. Therefore, the film forming device can decrease evaporation probability of the thick part of the film thickness, thereby controlling evaporation probability of the liquid film so as to be uniform throughout the whole of the liquid film.

In the film-forming device, the converting data may correlate a thin part of the liquid film with light with a high intensity.

According to the film forming device, the thin part of the film thickness receives high light energy. Therefore, the film forming device can increase evaporation probability of the thin part of the film thickness, thereby controlling evaporation probability of the liquid film to be uniform throughout the whole of the liquid film.

In the film-forming method, the detector may image interference light of the liquid film, while the controller may modulate the light from the second light source based on only a phase of the interference light in the dry mode.

According to the film-forming device, the light emitted from the second light source to the liquid film is modulated based only on the phase of the light from the liquid film. Therefore, the film-forming device can achieve the modulating process of the drying light with a simpler structure, and further, can improve the film thickness controllability of a thin film with a simpler structure.

In the film-forming method, the controller may modulate the light from the second light source based on data in which a random phase is added to the phase of the interference light.

According to the film-forming device, the light emitted from the second light source to the liquid film can suppress energy concentration thereof by adding the random phase. Therefore, in the film-forming device, the light energy for drying is dispersed on the liquid film, thereby improving flatness of the thin film.

In the film-forming device, the first light source and the second light source may be served by a single light source.

According to the film-forming device, the single light source emits light for measurement and light for drying. Therefore, the film-forming device can improve film thickness controllability of the thin film with a simpler structure.

### BRIEF DESCRIPTION OF THE DRAWINGS

The invention will be described with reference to the accompanying drawings, wherein like numbers reference like elements.

FIG. 1 is a perspective view illustrating a droplet discharge device according to a first embodiment of the invention.

FIG. 2 is a perspective view illustrating a droplet discharge head according to the first embodiment of the invention.

FIG. 3 is a side view schematically illustrating an inside of the droplet discharge head according to the first embodiment of the invention.

FIG. 4 is a plan view illustrating a droplet discharging position according to the first embodiment of the invention.

FIGS. 5A and 5B are side views schematically illustrating an inside of an irradiator according to the first embodiment of the invention.

FIGS. 6A and 6B are side views schematically illustrating the inside of the irradiator according to the first embodiment of the invention.

FIG. 7A is a sectional view schematically illustrating the irradiator.

FIG. 7B is a chart showing film thickness distribution.

FIG. 7C is a chart showing intensity distribution of light for drying.

FIG. 8 is an electrical block circuit diagram showing an electrical structure of the droplet discharge device according to the first embodiment of the invention.

FIG. 9 is a side view schematically illustrating an inside of an irradiator according to a second embodiment of the invention.

FIG. 10A is a sectional view schematically illustrating the irradiator.

FIG. 10B is a chart showing refractive-index distribution.

FIG. 10C is a chart showing intensity distribution of light for drying.

FIG. 11 is an electrical block circuit diagram illustrating an electrical structure of the droplet discharge device according to the second embodiment of the invention.

FIG. 12A is a plan view illustrating a droplet discharge process in related art, while FIG. 12B is a side view illustrating the same.

FIG. 13A is a plan view illustrating another droplet discharge process in related art, while FIG. 13B is a side view illustrating the same.

### DESCRIPTION OF EXEMPLARY EMBODIMENTS

### First Embodiment

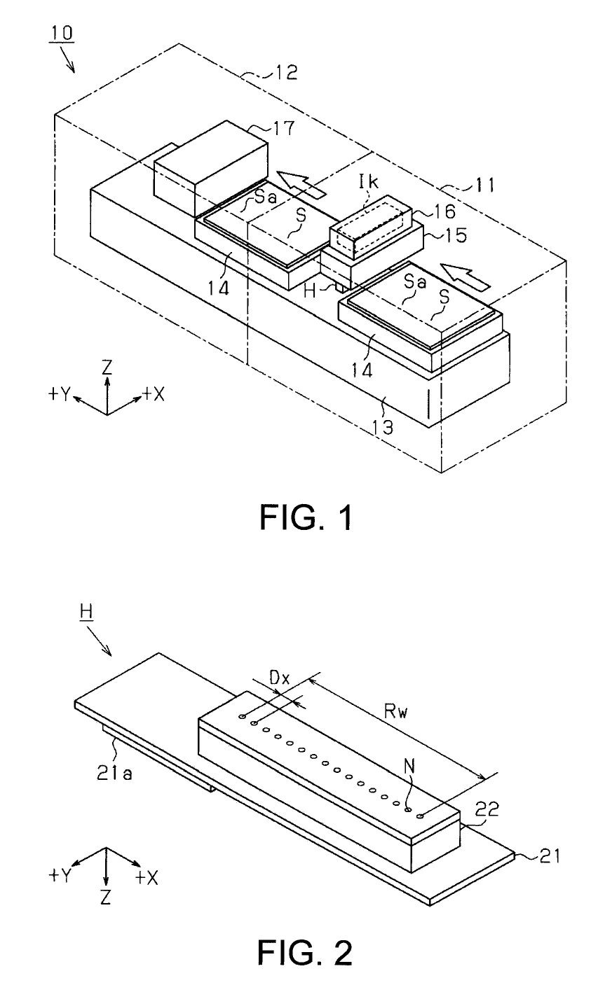

A first embodiment of the invention will be described below with reference to FIGS. 1 to 8. FIG. 1 is a perspective view of a droplet discharge device 10 as a film forming device.

Referring to FIG. 1, the droplet discharge device 10 includes a discharge unit 11 for discharging a droplet to a substrate S that is a target workpiece, and a dryer unit 12 for drying the discharged droplet. The discharge unit 11 and the dryer unit 12 include a base 13 and a substrate stage 14 in common. The base 13 extends in one direction and the substrate stage 14 on which the substrate S is to be placed is mounted on the base 13. The substrate stage 14 positions and fixes the substrate S in a manner allowing one surface of the substrate S to face up so as to transfer the substrate S to the discharge unit 11 or the dryer unit 12 by reciprocation between the discharge unit 11 and the dryer unit 12 along a longitudinal direction of the base 13. As the substrate S, a substrate such as a green sheet, a glass substrate, a silicon substrate, a ceramic substrate, a resin film, or the like can be used.

In the first embodiment, an upper surface of the substrate S is referred to as a discharge surface Sa. The discharge surface Sa is a surface to form a desired film, and has a position to land the droplet as a target point. A direction along which the substrate S is transferred, that is, a direction toward upper left in FIG. 1 is referred to as +Y direction. A direction orthogonal to +Y direction, that is, a direction toward upper right in FIG. 1 is referred to as +X direction, and a normal line direction of the substrate S is referred to as Z direction.

The discharge unit 11 includes a carriage 15 moving along +X direction and an opposite direction of +X direction (−X direction), and an ink tank 16 mounted on an upper side of the carriage 15. Further, the carriage 15 includes a plurality of droplet discharge heads H aligned nearly along +X direction on its lower side, thereby enabling a droplet discharge process employing a single scan method.

The carriage 15 moves in +X direction or −X direction when the substrate S is transferred in +Y direction so as to arrange the droplet discharge heads H above a transfer path of the target point. An action to transfer the substrate S in +Y direction and −Y direction is referred to as a main scan. Further, an action to transfer the droplet discharge heads H in +X direction and −X direction so as to arrange the droplet discharge heads H above the transfer path of the target point is referred to as a sub scan.

The ink tank 16 stores an ink Ik in a liquid state and guides the ink Ik that is stored out at a predetermined pressure. As the ink Ik, an ink such as an orientation film ink containing an orientation film material as a film material dispersed therein, an indium tin oxide (ITO) ink containing ITO fine particles dispersed therein, a silver ink containing silver fine particles dispersed therein, or the like can be used. The ink Ik discharged on the substrate S can form various thin films such as an orientation film, a transparent conductive film, and wiring through a predetermined drying process.

As the orientation film ink, for example, one prepared by dissolving polyimide or polyamic acid as an orientation film material in a mixed solvent of gamma-butyrolactone, butyl cellosolve, and N-methyl-2-pyrrolidone (A concentration of solid content with respect to a total mass of the ink is 8 wt %.) can be used. As a relative proportion of the mixed solvent, for example, gamma-butyrolactone is 93 wt %, while butyl cellosolve is 2 wt %, and N-methyl-2-pyrrolidone is 5 wt %.

As the silver ink, one prepared by dispersing silver fine particles having a grain diameter of 30 nm in a mixed solvent of water and xylitol with trisodium citrate as a dispersing aid can be used, for example. As a relative proportion of the silver ink, for example, water is 40 wt %, and xylitol is 20 wt %, while a weight of silver particles is 40 wt %.

The dryer unit 12 includes an irradiator 17 for irradiating a liquid film F0 formed on the substrate S with a laser beam B. While the main scan is performed on the substrate S, the irradiator 17 conducts a measurement process (measurement mode) for measuring a film thickness of the liquid film F0 passing through immediately below the irradiator 17, and a drying process (dry mode) for drying the liquid film F0. The irradiator 17 moves in +X direction and −X direction so as to conduct the measurement process and the drying process on the liquid film F0 through a whole of the discharge surface Sa.

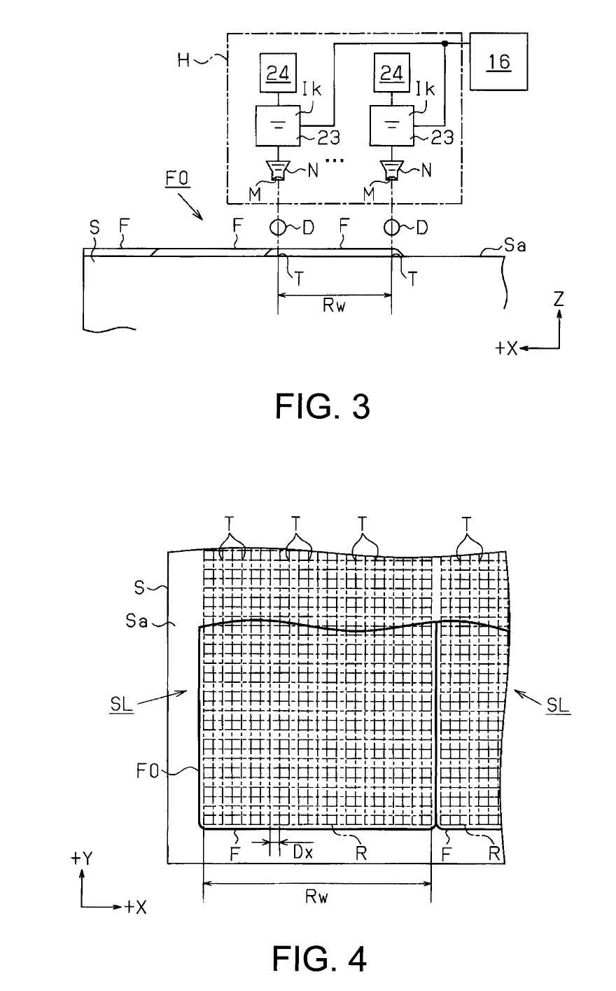

Next, the droplet discharge head H will be described with reference to FIGS. 2 to 4. FIG. 2 is a perspective view illustrating the droplet discharge head H viewed from the substrate stage 14. FIG. 3 is a diagram schematically illustrating an inside of the droplet discharge head H. FIG. 4 is a plan view illustrating a discharging position on which the droplet D is discharged with the droplet discharge head H.

Referring to FIG. 2, the droplet discharge head H includes a head substrate 21 extending in +X direction and a head body 22 mounted on the head substrate 21. The head substrate 21 is positioned and fixed by the carriage 15 and moves along +X direction and −X direction with respect to the substrate S. The head substrate 21 includes an input terminal 21a at an end side thereof so as to output various driving signals that are inputted into the input terminal 21a to the head body 22.

The head body 22 is provided with k (which is an integer number of 1 or more) pieces of nozzles N in +X direction along a nearly whole width of a surface facing to the substrate S. Each of the nozzles N is a circular hole extending in Z direction, and formed along +X direction at a predetermined pitch. The head body 22 is provided with 180 pieces of the nozzles N that are arranged along +X direction at a pitch of 141 μm. In the first embodiment, the pitch in which the nozzles N are formed is referred to as a nozzle pitch Dx, while a width of a nozzle row is referred to as a nozzle row width Rw. In FIG. 2, the number of nozzles N is simplified for explaining positions of the nozzles N.

Referring to FIG. 3, the head body 22 includes a cavity 23, and a pressure generating element 24 providing pressure to an inside of the cavity 23 so as to correspond to each of the nozzles N. That is, the head body 22 includes k pieces of the cavities 23, and k pieces of the pressure generating elements 24, which are the same number as the nozzles N. Each of the cavities 23 and each of the pressure generating elements 24 are arranged immediately above each of the nozzles N so as to correspond to each of the nozzles N. Each of the cavities 23 is coupled with the ink tank 16 that is shared by the cavities 23, stores the ink Ik from the ink tank 16, and supplies the ink Ik to a communicated nozzle among the nozzles N. Each of the nozzles N receives the ink Ik from a communicated cavity among the cavities 23 and forms a gas-liquid interface at its own opening (hereinafter, simply referred to as “meniscus M”).

Each of the pressure generating elements 24 provides a predetermined pressure to an inside of the communicated cavity among the cavities 23 so as to increase or decrease a pressure of the inside of the cavities 23, thereby vibrating the meniscus M of the nozzle communicated with the cavity 23. As the pressure generating elements 24, for example, piezoelectric elements that mechanically increase and decrease a volume of the cavities 23, or resistance heating elements that locally increase and decrease a temperature of the cavities 23 can be used.

As shown in FIG. 3, when a target point T on the discharge surface Sa is positioned immediately below a nozzle that is selected among the nozzles N (hereinafter, simply referred to as “selected nozzle”), a cavity communicated with the selected nozzle among the cavities 23 receives a drive force of corresponding one of the pressure generating elements 24, thereby vibrating the meniscus M of the selected nozzle so as to discharge a part of the ink Ik from the selected nozzle as the droplet D in a predetermined amount. The droplet D discharged from the selected nozzle of the nozzles N is landed on the target point T by traveling along a normal line of the discharge surface Sa.

Referring to FIG. 4, the discharge surface Sa of the substrate S includes a plurality of discharge regions R extending in +Y direction as shown by a dashed-dotted line. Each of the discharge regions R is a region having a width of the nozzle row width Rw in +X direction, and virtually divided by a dot pattern grid SL. A grid spacing in +Y direction and a grid spacing in +X direction in the dot pattern grid SL are determined by a discharge spacing of the droplet D. For example, the grid spacing in +Y direction in the dot pattern grid SL is determined by a product of a discharging cycle of each of the droplet discharge heads H and a main scanning velocity of the substrate S. The grid spacing in +X direction in the dot pattern grid SL is determined by the nozzle pitch Dx.

A selection whether the droplet D is discharged or not is determined on each grid point of the dot pattern grid SL. In the first embodiment, in order to form a partial liquid film F throughout a whole area of each of the discharge regions R, all grid points in the discharge regions R are selected as the target point T. In FIG. 4, the grid spacing of the dot pattern grid SL is enlarged for explaining the grid points of the dot pattern grid SL.

When the discharge process of the droplet D is conducted, each of the nozzles N of the discharge heads H is positioned on an extension line of a group of the target points T that are consecutively formed in +Y direction. When the main scan is performed on the substrate S, each of the nozzles N in one of the discharge heads H faces each of k pieces of the target points T aligned in +X direction at a same timing. That is, the droplet D is landed onto each of the k pieces of the target points T aligned in +X direction at a substantially same timing. The droplets D discharged in k pieces of them are landed and coalesce along +X direction, forming the partial liquid film F continuously formed in +X direction. The substantially same timing means a timing to form a liquid film continuing in +X direction from the k pieces of the droplets D that are landed at the k pieces of the target points T aligned in +X direction, but not to cause a film thickness difference between the droplets D due to a difference of a landing timing between the droplets D adjacent to each other. The group of the droplets D (k pieces of the droplets D) landed at the substantially same timing forms the partial liquid film F in a strip shape and extending along +Y direction by a subsequent group of the droplets D sequentially landed in −Y direction. Then, each of the discharge heads H forms the partial liquid film F extending in +Y direction along +X direction, thereby forming a plurality of partial liquid films F extending in +Y direction. The plurality of partial liquid films F adjacent to each other are united, forming one liquid film F0 on the whole of the discharge surface Sa.

In a case of forming an orientation film in 3 μm thick by using the orientation film ink described above, for example, the liquid film F0 is formed with the orientation film ink, and dried for 50 minutes at a room temperature. Alternatively, the liquid film F0 is heated to be at 40 degrees Celsius and dried for 30 minutes. Further alternatively, the liquid film F0 is heated to be at 100 degrees Celsius and provisionally dried for 1 minute, and then heated at 200 degrees Celsius and dried for 10 to 30 minutes. During the drying processes, butyl cellosolve in the orientation film ink evaporates first as it is respectively easy to evaporate, and a solvent component having high surface tension remains in the liquid film F0. Therefore, when a uniform amount of heat is provided to the liquid film F0, leveling proceeds in a center of the partial liquid film F and the liquid film F0. As a result, a film thickness difference starts being formed at an edge portion. In the first embodiment, during the drying processes, predetermined intensity distribution is provided to the liquid film F0, accelerating leveling in a whole of the liquid film F0.

In a case of forming a wiring in 10 μm thick by using the silver ink described above, for example, the liquid film F0 is formed with the silver ink, dried at 60 degrees Celsius, and then, fired at 900 degrees Celsius. In the first embodiment, before drying at 60 degrees Celsius, such predetermined intensity distribution is provided to the liquid film F0, accelerating leveling in the whole of the liquid film F0.

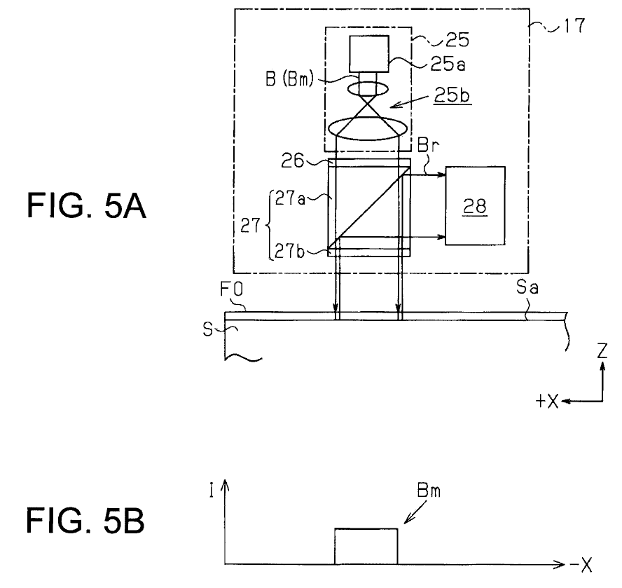

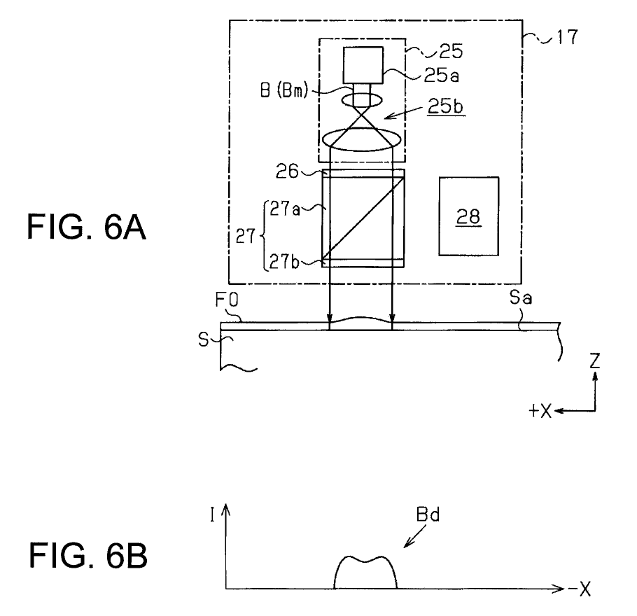

The irradiator 17 will now be described with reference to FIGS. 5A through 6B. FIGS. 5A and 6A are schematic views illustrating an inside of the irradiator 17. The irradiator 17 conducts the measurement process for measuring a film thickness of the liquid film F0 (hereinafter, simply referred to as “liquid thickness”), and the drying process for drying the liquid film F0, and includes an emitting portion 25, a modulating portion 26 and a branching portion 27 that configure the irradiator 17, and further an imaging portion 28 as a detector.

The emitting portion 25 includes a light source 25a serving as a first light source and a second light source, and an output optical system 25b configuring the irradiator 17. As the light source 25a, for example, a multiwavelength laser emitting a laser light beam, or a halogen lamp and a sodium lamp that emit a white light beam.

When the measurement mode is selected, the light source 25a selectively emits a light beam in a wavelength range for measuring an optical constant, or a shape of the liquid film F0, that is, the liquid thickness at each position of the liquid film F0. Further, when the dry mode is selected, the light source 25a selectively emits a light beam in a wavelength range for drying the liquid film F0.

The optical constant of the liquid film F0 in the first embodiment is an optical constant (reflectivity, refractive index, and extinction coefficient) related to a film thickness of a thin film. The ink Ik fluctuates a refractive index and an extinction coefficient depending on evaporation of the solvent component and the like. Therefore, by measuring the optical constant of the liquid film F0 and setting drying conditions according to the measuring result, an appropriate drying control corresponding to a drying state of the liquid film F0 can be achieved. Further, the ink Ik fluctuates the liquid thickness depending on evaporation of the solvent component and the like. Therefore, by measuring the film shape of the liquid film F0 and setting drying conditions according to the measuring result, an appropriate drying control corresponding to a drying state of the liquid film F0 can be achieved.

The output optical system 25b is an optical system formed with a collimator, a cylindrical lens, or the like, for example, and makes light from the light source 25a to be a parallel light beam extending to an XY plane and leads the parallel light beam to the modulating portion 26. In the first embodiment, the light to measure the liquid thickness is referred to as measuring light Bm, and the light to dry the liquid film F0 is referred to as drying light Bd.

The measuring light Bm is light reflected at a surface of the liquid film F0, and an interface of the liquid film F0 and the substrate S upon irradiation to the liquid film F0. When the measuring light Bm is reflected at the surface of the liquid film F0, and the interface of the liquid film F0 and the substrate S, reflected light Br is interference light caused by the liquid film F0 and includes information (an amplitude and a phase) related to the optical constant, or the shape of the liquid film F0.

The drying light Bd is light in a wavelength range to be absorbed to at least one of the liquid film F0, the substrate S, and the substrate stage 14, and preferably light in a wavelength range to be absorbed to the substrate S only. When the drying light Bd is absorbed to at least one of the liquid film F0, the substrate S, and the substrate stage 14, a portion to absorb the drying light Bd converts light energy into thermal energy, thereby heating the liquid film F0 in an irradiation region. When the drying light Bd is absorbed to the substrate S only, the substrate S absorbing the drying light Bd converts light energy of the drying light Bd into thermal energy, thereby heating the liquid film F0 in the irradiation region, while the liquid film F0 transmitting the drying light Bd prevents a surface of the liquid film F0 from locally drying.

The modulating portion 26 is, for example, a spatial light modulator (SLM) such as a liquid crystal display (LCD), a digital micro mirror device (DMD), an acoustooptic modulator (AOM), or the like, and a device having resolution to display an interference fringe of a light wave. When receiving a predetermined driving signal (hereinafter, referred to as “modulation data SC”), the modulating portion 26 displays an interference fringe (Fourier Transformation image) corresponding to the modulation data SC and receives light from the emitting portion 25, thereby changing light wave information such as an amplitude and a phase of the light.

When the measurement mode is selected, the modulating portion 26 receives the measuring light Bm from the emitting portion 25, and corrects the measuring light Bm to a plane wave. The modulating portion 26 appropriately modulates a phase of the measuring light Bm in order to obtain the interference fringe caused by the liquid film F0 by using the measuring light Bm.

When the dry mode is selected, the modulating portion 26 receives the drying light Bd from the emitting portion 25, and modulates an intensity and a wavefront of the drying light Bd, emitting the drying light Bd that has been modulated to the branching portion 27. The modulating portion 26 modulates the intensity and the wavefront of the drying light Bd corresponding to the optical constant (film composition) and the film shape of the liquid film F0 measured by the measuring light Bm.

The branching portion 27 includes a beam splitter 27a and a λ/4 phase difference plate 27b.

When the measurement mode is selected, the branching portion 27 receives the measuring light Bm from the modulating portion 26, and irradiates the discharge surface Sa with the measuring light Bm with a constant intensity I. The branching portion 27 receives the reflected light Br from a liquid film F0 side, and divides a light path of the reflected light Br from a light path of the measuring light Bm, leading the reflected light Br to the imaging portion 28. When the emitting portion 25 emits the measuring light Bm, the branching portion 27 thoroughly irradiates a whole of the irradiation region on the discharge surface Sa with the measuring light Bm with the intensity I, and leads interference light of light reflected at the surface of the liquid film F0 and light reflected at the interface between the liquid film F0 and the discharge surface Sa to the imaging portion 28.

When the dry mode is selected, the branching portion 27 receives the drying light Bd from the modulating portion 26, and leads the drying light Bd to the discharge surface Sa. When the emitting portion 25 emits the drying light Bd, the branching portion 27 leads the drying light Bd modulated by the modulating portion 26 to the discharge surface Sa with predetermined intensity distribution. That is, when the emitting portion 25 emits the drying light Bd, the branching portion 27 forms energy distribution by the drying light Bd in the irradiation region on the discharge surface Sa.

The imaging portion 28 has a function to detect an interference fringe related to the reflected light Br from the liquid film F0 side and includes an imaging element such as a diode array and a CCD array that have two dimensions for directly inputting the interference fringe. The interference fringe is inputted to the imaging portion 28 as a two-dimensional bit pattern and converted into an electrical signal so as to be outputted from the imaging portion 28. That is, the imaging portion 28 receives the reflected light Br and imports information related to an amplitude and a phase from all points of the liquid film F0 in the irradiation region into all points of the imaging element. In a case of using multiwavelength light as the measuring light Bm, the imaging portion 28 includes a light dispersive element such as a diffraction grating, an optical multilayer thin film, or the like for dispersing the reflected light Br, and detects the intensity of the reflected light Br by each wavelength.

When the measurement mode is selected, the emitting portion 25 irradiates the liquid film F0 with the measuring light Bm emitted from the light source 25a through the branching portion 27. The branching portion 27 receives the reflected light Br from the liquid film F0 side and leads the reflected light Br to the imaging portion 28. The reflected light Br includes a component reflected at the surface of the liquid film F0 and a component reflected at the interface of the liquid film F0 and the discharge surface Sa. The reflected light Br received at the imaging portion 28 is an interference wave having these two kinds of components. An interference fringe of the reflected light Br includes information related to a light path difference of the two kinds of components, that is, information related to a liquid thickness. The imaging portion 28 receives the reflected light Br through the branching portion 27, and converts a two-dimensional bit pattern corresponding to the interference fringe into an electrical signal, outputting the electrical signal.

In the first embodiment, the output signal of the imaging portion 28 is referred to as reflected light data TD. The reflected light data TD is two-dimensional bit pattern data and includes information about an amplitude and a phase of the reflected light Br, that is, the optical constant of the liquid film F0 or the film shape of the liquid film F0.

The reflected light data TD is converted into information related to the optical constant or the film shape of the liquid film F0 by a predetermined converting process. Here, the information related to the optical constant or the film shape each obtained by converting the reflected light data TD is referred to liquid film data.

For example, the amplitude and the phase of the reflected light data TD are extracted by Fourier transformation, and the amplitude and the phase having been extracted can configure the liquid film data. Alternatively, the reflected light data TD is converted into the liquid film data by Fresnel transformation that is repeated calculation for each block of a predetermined coordinate.

Further, for example, only a phase having a constant amplitude of the reflected light data TD is extracted by Fourier transformation, and the phase can configure the liquid film data. This allows high Fourier transformation to be employed, reducing load required for the converting process of the reflected light data TD.

Further, for example, only a phase having a constant amplitude of the reflected light data TD is extracted by Fourier transformation, and further a phase in which a random phase is added to the extracted phase may configure the liquid film data. This can randomly disperse amplitude distribution of an inverse Fourier transformation image generated based on the liquid film data. When spatially random phase distribution that is provided to a coherent wavefront, an interference pattern (speckle noise) is formed. Therefore, an optical image generated by using the liquid film data can suppress concentration of such energy. The random phase is a phase satisfying properties of even probability and irregularity.

When the dry mode is selected, the emitting portion 25 corrects the drying light Bd emitted from the light source 25a to a plane wave by the output optical system 25b, and inputs the plane wave to the modulating portion 26. The modulating portion 26 receives the modulation data SC and displays an interference fringe (Fourier transformation image) corresponding to the liquid film data. The modulating portion 26 modulates the intensity and the phase of the drying light Bd that are inputted corresponding to the liquid film data, and converts the intensity and the wavefront of the drying light Bd corresponding to the liquid film data.

When the drying light Bd is emitted to the liquid film F0, the substrate S absorbs light energy from the drying light Bd, so that temperature distribution corresponding to the intensity distribution of the drying light Bd is formed on the discharge surface Sa. Therefore, the irradiator 17 forms temperature distribution corresponding to the liquid film data along a direction of the surface of the discharge surface Sa.

The irradiator 17 repeats the measurement process and the drying process throughout the whole of the liquid film F0 until the liquid film F0 is dried. In the first embodiment, a film thickness of a first measurement by the irradiator 17 is referred to as a first film thickness, and a film thickness of a second measurement on the same position is referred to as a second film thickness. Successively, in the same manner, a film thickness of an ‘n’ time measurement is referred to as an ‘n’ film thickness.

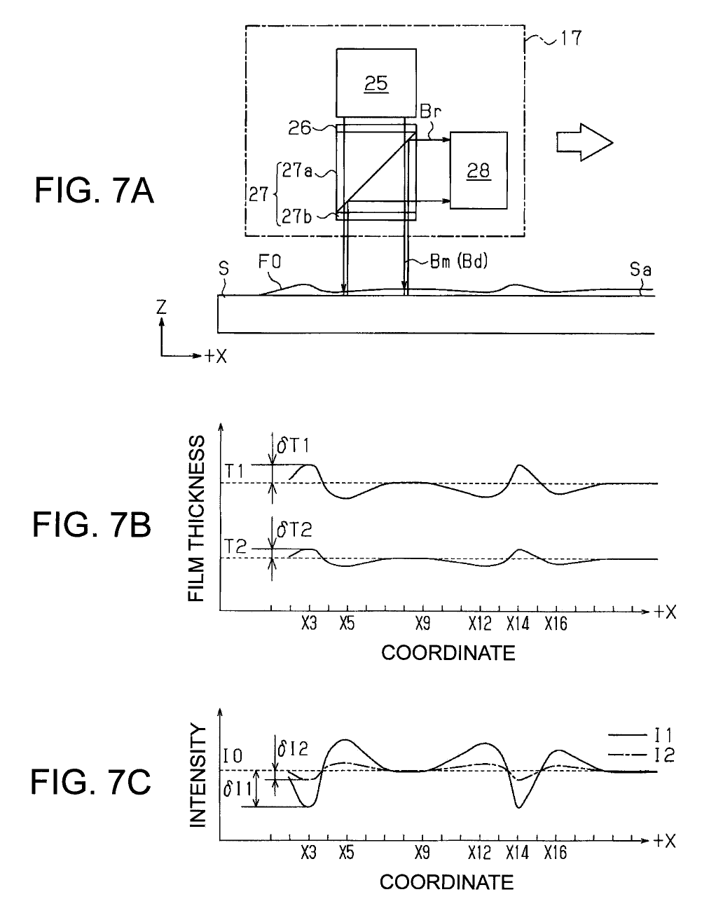

Next, the intensity distribution of the drying light Bd to be formed on the discharge surface Sa will be described below. FIG. 7A is a sectional view of the substrate S immediately after the discharge process of the droplet D. FIG. 7B shows film thickness distribution of the liquid film F0 measured by using the irradiator 17, while FIG. 7C shows the intensity distribution of the drying light Bd formed by using the irradiator 17.

Axes of abscissas in FIGS. 7B and 7C represent positions in +X direction of the discharge surface Sa, and a coordinate value thereof is standardized in a predetermined width. Further, in a description below, a case of making the film thickness of the thin film even by using the film shape of the liquid film F0 as the liquid film data, and drying the liquid film F0 after modulating the drying light Bd based on the film shape will be explained.

In FIG. 7A, when the measurement mode is selected, the irradiator 17 irradiates a surface of the liquid film F0 with the measuring light Bm from emitting portion 25 and measures the interference fringe of the reflected light Br.

In the droplet discharge process, the liquid film F0 is formed so that both edges of the discharge region R in +X direction are relatively thick as a portion having a thick film thickness in order to make a specific surface area in edges of partial liquid film F relatively large. For example, the liquid film F0 is formed so as to have relatively thick portions respectively on coordinates X3 and X14. Further, in the droplet discharge process, the liquid film F0 is formed with a film material flowing toward both edge portions, thereby forming portions having a relatively thin film thickness in a vicinity of the both edge portions. For example, the liquid film F0 is formed so as to have relatively thin portions immediately above the coordinates X5, X12, and X16.

In the first embodiment, an average value of the first film thickness in the whole of the liquid film F0 is referred to as a first average film thickness T1, and an average value of the second film thickness is referred to as a second average film thickness T2. Successively, in the same manner, an average value of the ‘n’ film thickness is referred to as an ‘n’ average film thickness. Further, a difference between the first average film thickness T1 and the first film thickness at each of the coordinates is referred to as a first film thickness difference value δT1, and a difference between the second average film thickness T2 and the second film thickness at each of the coordinates is referred to as a second film thickness difference value δT2. Successively, in the same manner, a difference between the ‘n’ average film thickness and the ‘n’ film thickness at each of the coordinates is referred to as an ‘n’ film thickness difference value.

Further, in FIG. 7A, when the dry mode is selected, the irradiator 17 forms the intensity distribution of the drying light Bd on the discharge surface Sa in order to compensate the film thickness difference value. In the first embodiment, an initial intensity provided on the liquid film F0 is referred to as a reference intensity I0. Further, distribution of the intensity I that is formed based on the first film thickness difference value δT1 is referred to as a first intensity I1, and distribution of the intensity I that is formed based on the second film thickness difference value δT2 is referred to as a second intensity I2. Successively, in the same manner, distribution of the intensity I that is formed based on the ‘n’ film thickness difference value is referred to as an ‘n’ intensity. Further, a difference between the reference intensity I0 and the first intensity I1 at each of the coordinates is referred to as a first film thickness difference value δI1, a difference between the reference intensity I0 and the second intensity I2 at each of the coordinates is referred to as a second intensity difference value δI2. Successively, in the same manner, a difference between the reference intensity I0 and the ‘n’ intensity at each of the coordinates is referred to as an ‘n’ intensity difference value.

The irradiator 17 decreases the intensity of the drying light Bd by an increased amount of the film thickness difference value, thereby decreasing a temperature of the liquid film F0 at a corresponding coordinate. On the contrary, the irradiator 17 increases the intensity of the drying light Bd by a decreased amount of the film thickness difference value, thereby rising a temperature of the liquid film F0 at a corresponding coordinate.

For example, when the irradiator 17 completes the first measurement process, the irradiator 17 lowers the intensity of the drying light Bd in respective regions of the coordinates X3, and X14 by the first film thickness difference value δT1 so as to lower the temperature of the liquid film F0 at the coordinates X3 and X14. On the contrary, the irradiator 17 increases the intensity of the drying light Bd by the first film thickness difference value δT1 in respective regions of the coordinates X5, X12, and X16 so as to rise the temperature of the liquid film F0 at the coordinates X5, X12, and X16.

At this time, the portions whose film thickness is relatively thick (e.g. the coordinates X3 and X14), and the portions whose film thickness is relatively thin (the coordinates X5, X12, and X16) can have nearly same evaporation probability of evaporation components according to the intensity distribution to be formed. Therefore, flow of the film material is suppressed, so that concentration of the film material of the liquid film F0 is gradually equalized on the whole of the liquid film F0.

Then, when the irradiator 17 completes the first drying process, and completes the second measurement, the irradiator 17 decreases the intensity of the drying light Bd in respective regions of the coordinates X3, and X14 by the second film thickness difference value δT2 so as to lower the temperature of the liquid film F0 at the coordinates X3 and X14. On the contrary, the irradiator 17 increases the intensity of the drying light Bd in respective regions of the coordinates X5, X12, and X16 by the second film thickness difference value δT2 so as to rise the temperature of the liquid film F0 at the coordinates X5, X12, and X16.

At this time, the portions whose film thickness is relatively thick (e.g. the coordinates X3 and X14), and the portions whose film thickness is relatively thin (the coordinates X5, X12, and X16) can be formed so that the second film thickness difference value δT2 is smaller than the first film thickness difference value δT1, while the second intensity difference value δI2 is smaller than the first intensity difference value δI1 because the first intensity difference value δI1 is preliminarily formed. That is, the droplet discharge device 10 can make the ‘n’ film thickness difference value smaller than an ‘n−1’ film thickness difference value because the intensity distribution based on the ‘n−1’ film thickness difference value is preliminarily formed. As a result, the droplet discharge device 10 can improve film thickness uniformity of the liquid film F0 after the drying process in accordance with the number of times to form the intensity distribution.

Further, at this time, in a case where the liquid film data is generated by adding a random phase, spatially random phase distribution is provided on a wavefront of the drying light Bd, thereby providing amplitude distribution based on speckle noise. As a result, errors can be dispersed to the intensity of the drying light Bd, further improving the film thickness uniformity of the liquid film F0 after the drying process.

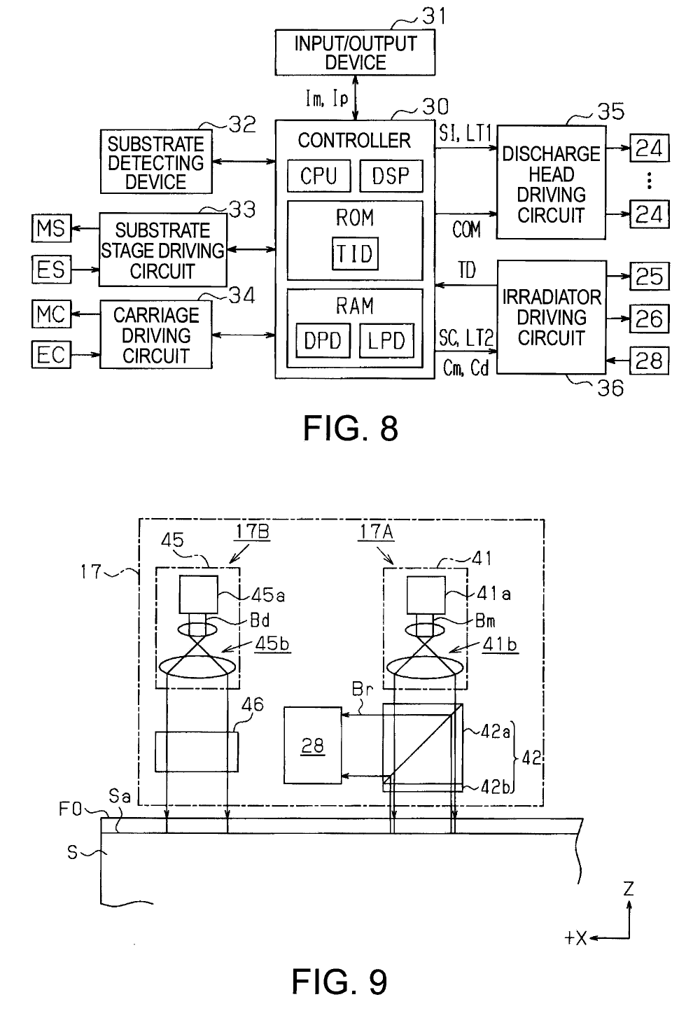

An electrical structure of the droplet discharge device 10 structured as above will now be described with reference to FIG. 8. FIG. 8 is an electrical block circuit diagram showing the electrical structure of the droplet discharge device 10.

Referring to FIG. 8, a controller 30 includes a CPU, a DSP, a ROM, a RAM, and so on. The controller 30 conducts the main scan of the substrate S with the substrate stage 14, the sub scan of the droplet discharge heads H with the carriage 15, the droplet discharge process with the droplet discharge heads H, the measurement process of a liquid thickness with the irradiator 17, and the drying process for the liquid film F0 in accordance with various controlling programs and various data stored in the ROM and the RAM that serve as memory.

The controller 30 stores converting data TID in the ROM. The converting data TID is data that correlates a plurality of various optical constants or a plurality of various liquid thicknesses with light wave information of the drying light Bd based on a target film thickness of the thin film. The controller 30 converts the optical constant of the liquid film F0, or the liquid film data related to the film shape into data for modulating the drying light Bd by the converting data TID. For example, the converting data TID is a look-up table indicating a relation of a plurality of various film thickness difference values respectively to intensity difference values as the light wave information, and preliminarily set based on various tests. The controller 30 converts distribution of the film thickness difference values included in the liquid film data into distribution of the intensity difference values by the converting data TID.

The liquid film F0 having the plurality of various optical constants or the plurality of various liquid thicknesses receives the drying light Bd with the light wave information based on the converting data TID, thereby standardizing the film thickness after the drying process. For example, the liquid film F0 having the plurality of film thickness difference values that are different from each other can uniform the film thickness after the drying process by using the intensity difference value based on the converting data TID.

The controller 30 is coupled to an input/output device 31 including various operating switches and a display so as to receive various signals outputted from the input/output device 31. The controller 30 receives a mode selection signal Im for selecting a process mode from the input/output device 31. Further, the controller 30 receives process data Ip having a predetermined format from the input/output device 31. The process data Ip is used for performing the droplet discharge process, the measurement process, and the drying process. In the first embodiment, the input/output device 31 configures a mode selector.

The mode selection signal Im is a signal for selecting one of the measurement mode and the dry mode as a process operation of the irradiator 17. The process data Ip includes data for performing various processes such as target film thickness data related to the film thickness distribution of the thin film, drawing data for drawing the liquid film F0, and intensity data related to the reference intensity I0 for drying the liquid film F0.

When receiving the mode selection signal Im from the input/output device 31, the controller 30 allows the irradiator 17 to selectively conduct the process operation based on the mode selection signal Im, that is, one of the measurement process and the drying process.

When the controller 30 receives the process data Ip from the input/output device 31, the controller 30 conducts a predetermined expanding process with respect to the process data Ip so as to generate dot pattern data DPD. The dot pattern data DPD has a bit length that is same as the number of grid points of the dot pattern grid SL, and defines whether the droplet D is discharged or not on each of the grid points of the dot pattern grid SL. That is, the dot pattern data DPD defines “on” or “off” of each of the pressure generating elements 24 in accordance with a value (“0” or “1”) of each bit.

When the controller 30 receives the process data Ip from the input/output device 31, the controller 30 conducts a predetermined expanding process with respect to the process data Ip so as to generate and store data related to the reference intensity I0 (hereinafter, simply referred to as “reference intensity data LPD”).

The controller 30 is coupled to a substrate detecting device 32. The substrate detecting device 32 has an imaging function or the like for detecting an end edge of the substrate S. The controller 30 calculates a relative position of each of the target points T with respect to the droplet discharge heads H and calculates a relative position of the substrate S with respect to the irradiator 17 based on a detecting signal received from the substrate detecting device 32.

The controller 30 is coupled to a substrate stage driving circuit 33 and inputs a control signal corresponding to the substrate stage driving circuit 33 into the circuit 33. The substrate stage driving circuit 33 normally or reversely rotates a stage motor MS for moving the substrate stage 14 in response to the control signal from the controller 30. The substrate stage driving circuit 33 receives a detecting signal from a stage motor encoder ES, and calculates a rotating direction and a rotating speed of the stage motor MS.

The controller 30 calculates a moving direction and a moving amount of the substrate stage 14 based on a calculating result from the substrate stage driving circuit 33 so as to judge whether a target point among the target points T of the discharge surface Sa is positioned immediately below a corresponding nozzle among the nozzles N or not. The controller 30 calculates the moving direction and the moving amount of the substrate stage 14 based on the calculating result from the substrate stage driving circuit 33 so as to judge whether each position of the discharge regions R is positioned immediately below the irradiator 17 or not.

The controller 30 generates a discharge timing signal LT1 every time each of the target points T is positioned immediately below each corresponding nozzle among the nozzles N so as to output the discharge timing signal LT 1 to a discharge head driving circuit 35. The controller 30 generates an irradiation timing signal LT2 every time each position of the discharge regions R is positioned immediately below the irradiator 17 so as to output the irradiation timing signal LT 2 to an irradiator driving circuit 36.

The controller 30 is coupled to a carriage driving circuit 34 so as to input a control signal corresponding to the carriage driving circuit 34 to the circuit 34. The carriage driving circuit 34 normally or reversely rotates the carriage motor MC for moving the carriage 15 in response to the control signal from the controller 30.

The carriage driving circuit 34 receives a detecting signal from a carriage motor encoder EC, and calculates a rotating direction and a rotating speed of the carriage motor MC. The controller 30 calculates a moving direction and a moving amount of the carriage 15 based on a calculating result from the carriage driving circuit 34 so as to position each of the nozzles N on a main scan path of one of the target points T.

The controller 30 is coupled to the discharge head driving circuit 35 and inputs the discharge timing signal LT1 and a driving waveform signal COM for operating the pressure generating elements 24 to the discharge head driving circuit 35. The controller 30 generates a serial pattern data SI for serially transferring the dot pattern data DPD and serially transfers the serial pattern data SI to the discharge head driving circuit 35. The discharge head driving circuit 35 receives the serial pattern data SI from the controller 30 and then performs serial/parallel conversion of the data SI so as to generate parallel pattern data for allowing each bit value to correspond to one of k pieces of the nozzles N, that is, one of k pieces of the pressure generating elements 24. When receiving the discharge timing signal LT1 from the controller 30, the discharge head driving circuit 35 supplies the driving waveform signal COM to the pressure generating element 24 to which a discharging operation is required based on the parallel pattern data. In the first embodiment, when receiving the discharge timing signal LT1, the discharge head driving circuit 35 supplies the driving waveform signal COM to all of the pressure generating elements 24. Thus the controller 30 lands the droplet D on each of the target points T continuously arranged along +X direction.

The controller 30 is coupled to the irradiator driving circuit 36. The controller 30 outputs a measuring light selection signal Cm for allowing the light source 25a to emit the measuring light Bm. The controller 30 outputs a drying light selection signal Cd for allowing the light source 25a to emit the drying light Bd. The irradiator driving circuit 36 operates the emitting portion 25 in response to the signal from the controller 30, and emits the measuring light Bm or the drying light Bd from the emitting portion 25.

The irradiator driving circuit 36 performs A/D conversion of an output signal from the imaging portion 28, and inputs the reflected light data TD related to the interference fringe of the reflected light Br to the controller 30. The controller 30 generates the liquid film data by various converting processes using the reflected light data TD, and conducts various calculation processes to modulate the drying light Bd. For example, the controller 30 generates the liquid film data based on the reflected light data TD, and calculates the liquid thickness of each of the coordinates, and a difference value (film thickness difference value) between a film thickness and the target film thickness at each of the coordinates on each occasion. In the first embodiment, the controller 30 extracts only a phase having a constant amplitude by Fourier transformation using the reflected light data TD, and further generates the liquid film data by adding a random phase to the extracted phase.

When the measurement mode is selected, the controller 30 corrects the measuring light Bm to a plane wave, and generates the modulation data SC to obtain the interference fringe of the reflected light Br. When receiving the irradiation timing signal LT2, the irradiator driving circuit 36 operates the modulating portion 26 based on the modulation data SC from the controller 30, corrects the measuring light Bm to a plane wave, and displays the interference fringe to obtain the interference fringe of the reflected light Br on the modulating portion 26.

When the dry mode is selected, the controller 30 reads out the converting data TID stored in the ROM, and then converts an optical constant or a liquid thickness at each of the coordinates on each occasion based on the target film thickness into light wave information of the drying light Bd so as to generate the modulation data SC for modulating the drying light Bd. For example, when the dry mode is selected, the controller 30 converts the film thickness difference value at each of the coordinates on each occasion into an intensity difference value, and generates the modulation data SC to obtain the intensity difference value. When receiving the irradiation timing signal LT2, the irradiator driving circuit 36 operates the modulating portion 26 based on the modulation data SC from the controller 30, and forms the drying light Bd in intensity distribution corresponding to the liquid film data based on the target film thickness data.

A film-forming method with the droplet discharge device 10 will now be described. In a description below, a case of uniforming the film thickness of the thin film by using the film shape of the liquid film F0 as liquid film data, and drying the liquid film F0 after modulating the drying light Bd corresponding to the film shape will be explained.

As shown in FIG. 1, the substrate S is placed on the substrate stage 14 in a manner allowing the discharge surface Sa of the substrate S to face up. At this time, the substrate S is arranged in the discharge unit 11. When receiving the process data Ip from the input/output device 31, the controller 30 generates the dot pattern data DPD and the reference intensity data LPD based on the process data Ip and stores them.

The controller 30 operates the carriage motor MC through the carriage driving circuit 34 so as to arrange each of the nozzles N above the main scan path of each of the targets points T. Then the controller 30 operates the stage motor MS through the substrate stage driving circuit 33 so as to start the main scan of the substrate S.

The controller 30 calculates a relative position of each of the target points T with respect to the droplet discharge heads H based on a detecting signal received from the substrate detecting device 32, and calculates a relative position thereafter based on a calculating result received from the substrate stage driving circuit 33. The controller 30 judges whether each of the target points T is positioned immediately below one of the nozzles N or not based on the relative position of each of the target points T with respect to the droplet discharge heads H. Every time each of the target points T is positioned immediately below one of the nozzles N, the controller 30 generates and outputs the discharge timing signal LT1 to the discharge head driving circuit 35. That is, every time the k pieces of the target points T continuously arranged in +X direction are positioned immediately below the k pieces of the nozzles N, the controller 30 lands the droplets D to the k pieces of the target points T. The droplets D on the target points T form a plurality of partial liquid films F extending in +Y direction. The plurality of partial liquid films F coalesce along +X direction so as to form one liquid film F0 on the whole of the discharge surface Sa.

When receiving the mode selection signal Im for selecting the measurement mode from the input/output device 31, the controller 30 calculates a relative position of the discharge regions R with respect to the irradiator 17 by using the calculation result from the substrate stage driving circuit 33, and starts the measurement process of the liquid thickness when each position of the discharge regions R is positioned immediately below the irradiator 17. That is, the controller 30 outputs the measuring light selection signal Cm to the irradiator driving circuit 36 so as to allow the light source 25a to emit the measuring light Bm through the irradiator driving circuit 36. The controller 30 corrects the measuring light Bm to a plane wave through the irradiator driving circuit 36, and displays the interference fringe to obtain the interference fringe of the reflected light Br on the modulating portion 26. Then, the controller 30 calculates a film thickness difference value of each of the coordinates in response to the reflected light data TD received from the imaging portion 28 and reads out the converting data TID, converting the film thickness difference value of each of the coordinates on each occasion into an intensity difference value. The controller 30 thus completes the first measurement process.

When receiving the mode selection signal Im for selecting the dry mode from the input/output device 31, the controller 30 calculates a relative position of the discharge regions R with respect to the irradiator 17 by using the calculation result from the substrate stage driving circuit 33, and starts the drying process of the liquid film F0 when each position of the discharge regions R is positioned immediately below the irradiator 17.

The controller 30 generates the modulation data SC for obtaining each intensity difference value and outputs the modulation data SC to the irradiator driving circuit 36. The controller 30 operates the irradiator 17 through the irradiator driving circuit 36 so as to form the intensity distribution of the drying light Bd corresponding to the liquid film data based on the target film thickness data at each position of the discharge regions R. Thus, the controller 30 can improve film thickness controllability of the liquid film F0 in the drying process because the intensity distribution corresponding to the film thickness difference values is formed.

Thereafter, the controller 30 similarly repeats the measurement process and the drying process until the liquid film F0 is dried. Further, every time the measurement process is completed, the controller 30 updates the reflected light data TD, thereby continuously forming the intensity distribution corresponding to the liquid film data. Thus, the controller 30 can improve the film thickness controllability of the liquid film F0 after the drying process because the intensity distribution is updated.

Here, advantageous effects of the first embodiment will be described.

1. In the first embodiment, the measuring light Bm from the light source 25a is emitted to the liquid film F0 so as to detect the reflected light Br from the liquid film F0, thereby generating the liquid film data related to the thickness of the liquid film F0. Then, based on the converting data TID indicating a relation between the liquid film data and the light wave information of light, the drying light Bd from the light source 25a is modulated corresponding to the liquid film data. The drying light Bd having been modulated is emitted on the liquid film F0 so as to dry the liquid film F0.

Therefore, the drying light Bd to be emitted on the liquid film F0 is modulated based on the thickness of the liquid film F0. In the film forming method described above, the drying light Bd is modulated based on the thickness of the liquid film F0, thereby improving film thickness controllability of the thin film.

2. Further, the drying light Bd for drying the liquid film F0 and the measuring light Bm for generating the liquid film data are emitted from the light source 25a in common. Therefore, in the film forming method described above, improvement of positional matching between the measuring light Bm and the drying light Bd is achieved, and further a drying state and a shape of the liquid film F0 are controllable with higher alignment accuracy.

3. In the first embodiment above, the light wave information is information related to a light intensity. In the dry mode, the intensity of the drying light Bd is modulated corresponding to the liquid film data, and the drying light Bd having been modulated is emitted on the liquid film F0 so as to dry the liquid film F0. Therefore, the intensity of the drying light Bd to be emitted on the liquid film F0 is modulated based on the thickness of the liquid film F0. The film forming method described above thus can improve the film thickness controllability of a thin film because the intensity of the drying light Bd is modulated.

4. In the first embodiment above, the liquid film data is generated by imaging interference light caused by the liquid film F0. Then, the drying light Bd is modulated based on only a phase of the liquid film data. This can achieve the modulating process of the drying light Bd with a simpler structure, and further, can improve the film thickness controllability of the thin film with a simpler method.

5. In the first embodiment, the drying light Bd is modulated based on data in which a random phase is added to a phase of the liquid film. Therefore, the drying light Bd to be emitted on the liquid film F0 can suppress energy concentration thereof by adding the random phase. The drying light Bd thus can disperse the light energy on the liquid film F0, thereby improving flatness of the thin film.

6. In the first embodiment above, light in a wavelength range having low absorption of the ink Ik, but high absorption of the substrate S is emitted as the drying light Bd. Therefore, the energy of the drying light Bd is converted into thermal energy by the substrate S, and then provided to the liquid film F0. Thus, the liquid film F0 is prevented from locally drying or rapidly drying, more assuredly improving the film thickness controllability of the thin film.

### Second Embodiment

A second embodiment of the invention will be described below with reference to FIGS. 9 to 11. In the second embodiment, the irradiator 17 in the first embodiment is altered. Therefore, the alteration will be mainly described in detail. Elements that are common to the first embodiment are indicated by the same reference numerals.

Referring to FIG. 9, the irradiator 17 includes a measurement irradiator 17A for measuring a liquid thickness, and a drying irradiator 17B for drying the liquid film F0.

The measurement irradiator 17A includes an emitting portion 41 for measurement, a branching portion 42 for measurement configuring a first irradiator, and the imaging portion 28 as a detector. The emitting portion 41 includes a measuring light source 41a as a first light source, and a measuring optical system 41b configuring the first irradiator.

As the measuring light source 41a, for example, a multiwavelength laser emitting a laser light beam, or a halogen lamp and a sodium lamp that emit a white light beam. The measuring optical system 41b is an optical system formed with a collimator, a cylindrical lens, or the like, for example, and makes the measuring light Bm from the measuring light source 41a be a parallel light beam extending to an XY plane and leads the parallel light beam to the branching portion 42.

When the measurement mode is selected, the measuring light source 41a emits the measuring light Bm for measuring the optical constant, or the film shape of the liquid film F0 related to the film thickness of the thin film, that is, a liquid thickness at each position of the liquid film F0, and then leads the measuring light Bm to the branching portion 42 through the measuring optical system 41b. A wavelength range of the measuring light Bm is preferably a wavelength range that is not absorbed by the substrate S, the liquid film F0, and the substrate stage 14. When the dry mode is selected, the measuring light source 41a stops emission of the measuring light Bm so as to stand by until the measurement mode is selected.

The branching portion 42 includes a beam splitter 42a and a λ/4 phase difference plate 42b. The branching portion 42 receives the measuring light Bm from the emitting portion 41, and irradiates the discharge surface Sa with the measuring light Bm with a constant intensity I. The branching portion 42 receives the reflected light Br from the liquid film F0 side, and divides a light path of the reflected light Br from a light path of the measuring light Bm so as to lead the reflected light Br to the imaging portion 28.

The imaging portion 28 includes a light dispersive element such as a diffraction grating, an optical multilayer film, or the like for dispersing the reflected light Br, and detects an intensity of the reflected light Br that is dispersed by the light dispersive element by each wavelength.

When the measurement mode is selected, the emitting portion 41 irradiates the liquid film F0 with the measuring light Bm emitted from the measuring light source 41a through the branching portion 42. The branching portion 42 receives the reflected light Br from the liquid film F0 side and leads the reflected light Br to the imaging portion 28. Similarly to the first embodiment, the imaging portion 28 receives the reflected light Br through the branching portion 42, and outputs the reflected light data TD corresponding to an interference fringe.

The reflected light data TD is, similarly to the first embodiment, converted into liquid film data such as the optical constant or information related to the film shape of the liquid film F0 by a predetermined converting process. That is, the liquid film data includes an amplitude and a phase of the reflected light Br, for example. The amplitude and the phase of the reflected light Br are extracted by Fourier transformation, Fresnel transformation, or the like using the reflected light data TD. Alternatively, similarly to the first embodiment, the liquid film data may be configured with data in which only a phase having a constant amplitude of the reflected light data TD is extracted by Fourier transformation, and a random phase is added to the extracted phase, for example. Therefore, similarly to the first embodiment, an optical image generated by using the liquid film data can suppress concentration of such energy.

The measurement irradiator 17A conducts the measurement process throughout the whole of the liquid film F0 until the liquid film F0 is dried. In the second embodiment, an optical constant of a first measurement by the measurement irradiator 17A is referred to as a first optical constant, and an optical constant of a second measurement on the same position is referred to as a second optical constant. Successively, in the same manner, an optical constant of a ‘j’ time measurement is referred to as a ‘j’ optical constant Nj.

When the dry mode is selected, the emitting portion 41 stops emission of the measuring light Bm from the measuring light source 41a so as to stand by until the measurement mode is selected.

The drying irradiator 17B includes an emitting portion 45 for drying and a modulating portion 46 for drying. The emitting portion 45 includes a drying light source 45a and a drying optical system 45b.

As the drying light source 45a, for example, a single wavelength laser and a multiwavelength laser that emit a laser light beam, or a halogen lamp and a sodium lamp that emit a white light beam can be used. The drying optical system 45b is an optical system formed with a collimator, a cylindrical lens, or the like, for example, and makes the drying light Bd from the drying light source 45a be a parallel light beam extending to an XY plane and leads the parallel light beam to the modulating portion 46 for drying.

As the modulating portion 46, similarly to the modulating portion 26 in the first embodiment, an SLM such as an LCD, a DMD, an AOM or the like can be used. When receiving the modulation data SC, the modulating portion 46 displays an interference fringe corresponding to the modulation data SC (Fourier transformation image), and changes light wave information such as an amplitude and a phase of light by receiving the light from the emitting portion 45.

When the dry mode is selected, the drying light source 45a emits the drying light Bd for drying the liquid film F0. The modulating portion 46 receives the drying light Bd from the emitting portion 45, and modulates an intensity and a wavefront of the drying light Bd corresponding to the optical constant (film composition) and the film shape of the liquid film F0. The drying light Bd is, similarly to the first embodiment, light in a wavelength range that is absorbed by at least one of the liquid film F0, the substrate S, and the substrate stage 14, and preferably light in a wavelength range that is absorbed by the substrate S only.

The drying irradiator 17B changes the light wave information and modulates the intensity or the wavefront of the drying light Bd every time the measurement irradiator 17A conducts the measurement process. In the second embodiment, an intensity I that is formed based on the first optical constant is referred to as a first intensity I1, and an intensity I that is formed based on the second optical constant is referred to as a second intensity I2. Successively, in the same manner, an intensity I that is formed based on the ‘j’ optical constant Nj is referred to as a ‘j’ intensity Ij.

When the measurement mode is selected, the emitting portion 45 stops emission of the drying light Bd from the drying light source 45a so as to stand by until the dry mode is selected.

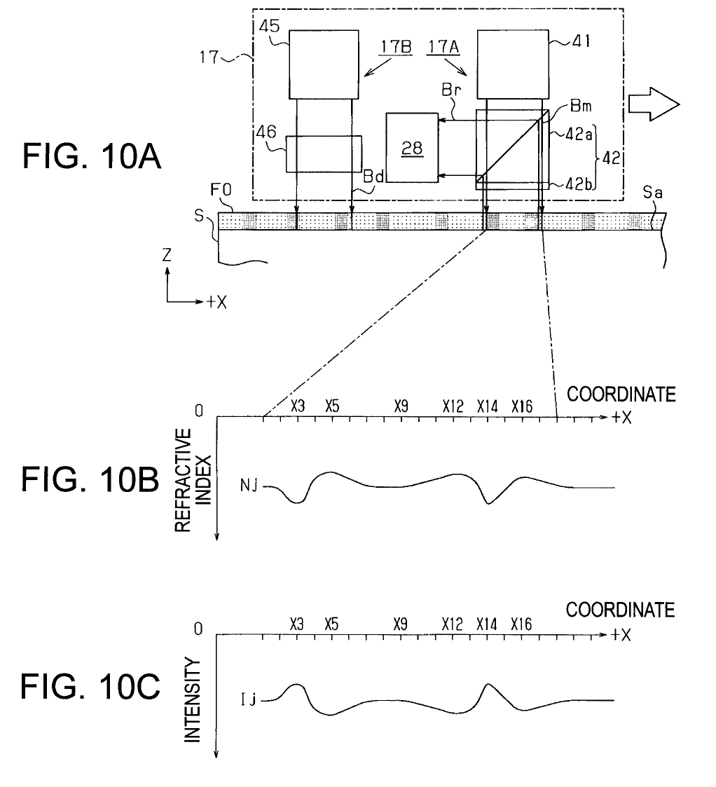

Next, intensity distribution of the drying light Bd to be formed on the discharge surface Sa will be described below. FIG. 10A is a sectional view of the substrate S immediately after the discharge process of the droplet D. FIG. 10B shows refractive index distribution of the liquid film F0 measured with the irradiator 17, while FIG. 10C is intensity distribution of the drying light Bd formed by using the irradiator 17.

Axes of abscissas in FIGS. 10B and 10C represent positions in +X direction of the discharge surface Sa, and coordinate values thereof are standardized in a predetermined width. Further, in a description below, a case of uniforming the film thickness of the thin film by using the optical constant (refractive index) of the liquid film F0 as the liquid film data, and drying the liquid film F0 after modulating the drying light Bd based on the optical constant will be explained.

In FIG. 10A, when the measurement mode is selected, the irradiator 17 irradiates a surface of the liquid film F0 with the measuring light Bm from the measurement emitting portion 17A, and measures an interference fringe of the reflected light Br.

In the droplet discharge process, the liquid film F0 can flow the film material in response to difference of evaporation rates in +X direction and a convection flow along +X direction. Then, regardless of the film thickness, the liquid film F0 forms a high concentration part and a low concentration part of the film material in +X direction, forming distribution of the optical constant in +X direction.

In FIG. 10A, the high concentration part is shown by dark grayscale, while the low concentration part is shown by light grayscale. In the FIG. 10B, the liquid film F0 is formed so as to have the high concentration part on each of the coordinates X3 and X14, thereby indicating a high refractive index. Further, the liquid film F0 is formed so as to have the low concentration part on immediately above each of the coordinates X5, X12, and X16 respectively, thereby indicating a low refractive index.

In FIG. 10C, when the dry mode is selected, the irradiator 17 forms the intensity distribution of the drying light Bd on the discharge surface Sa in order to compensate the refractive index distribution. That is, the irradiator 17 decreases the intensity of the drying light Bd by an increased amount of the refractive index, thereby reducing light energy to be provided on the high concentration part, and decreasing a temperature of the high concentration part. On the contrary, the irradiator 17 increases the intensity of the drying light Bd by a decreased amount of the refractive index, thereby increasing a temperature of the low concentration part of the liquid film F0.

For example, when the irradiator 17 completes the ‘j’ measurement process, the irradiator 17 decreases the intensity of the drying light Bd by an amount of the refractive index that is relatively increased in the regions of the coordinates X3, and X14 so as to lower the temperature of the liquid film F0 at the coordinates X3 and X14. On the contrary, the irradiator 17 increases the intensity of the drying light Bd by an amount of the refractive index that is relatively decreased in regions of the coordinates X5, X12, and X16 so as to rise the temperature of the liquid film F0 at the coordinates X5, X12, and X16.

At this time, concentration of the film material in a part whose refractive index is relatively high (e.g. the coordinates X3 and X14), and a part whose refractive index is relatively low (the coordinates X5, X12, and X16) is uniformed due to the intensity distribution to be formed. Further, the droplet discharge device 10 can make the ‘j’ optical constant distribution more even than a ‘j−1’ optical constant distribution because the intensity distribution based on the ‘j−1’ optical constant is preliminarily formed. As a result, the droplet discharge device 10 can improve film thickness uniformity of the thin film in accordance with the number of times to conduct the optical constant measurement and intensity distribution forming.

Further, at this time, since the liquid film data is generated by adding a random phase, spatially random phase distribution is provided on a wavefront of the drying light Bd, thereby providing amplitude distribution based on speckle noise. As a result, errors can be dispersed to the intensity of the drying light Bd, further improving the film thickness uniformity of the liquid film F0 after the drying process.

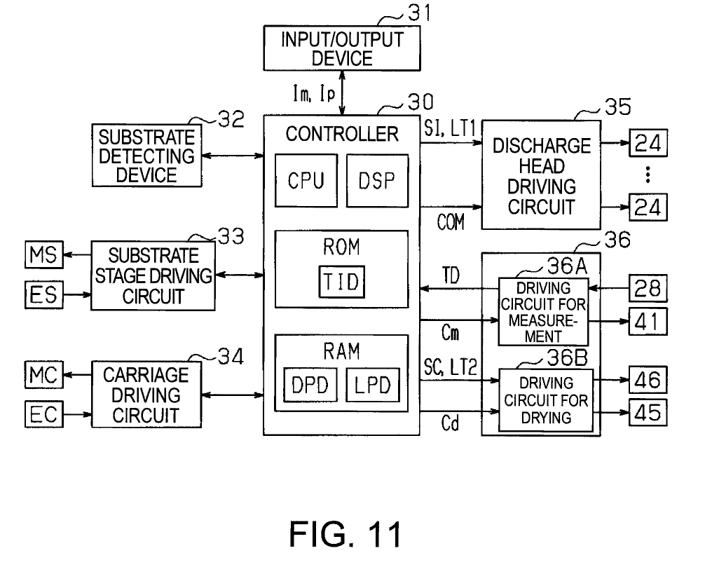

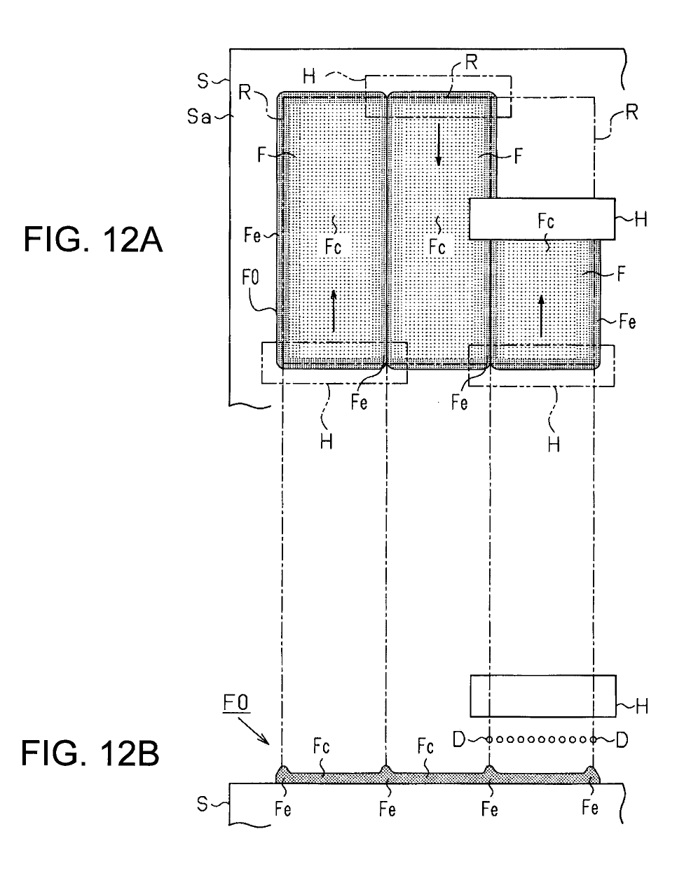

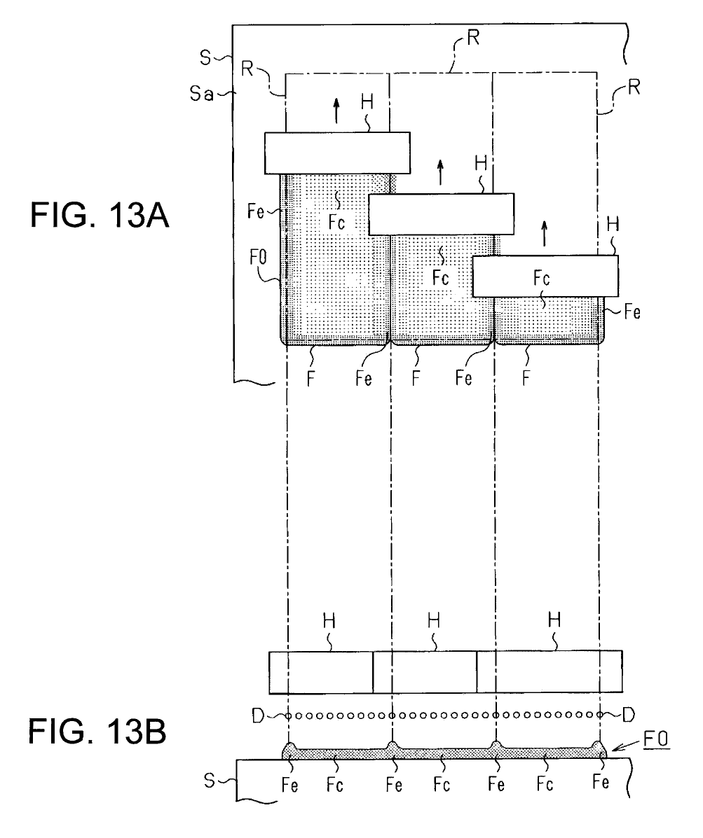

An electrical structure of the droplet discharge device 10 according to the second embodiment will now be described with reference to FIG. 11. FIG. 11 is an electrical block circuit diagram showing the electrical structure of the droplet discharge device 10.

Referring to FIG. 11, the controller 30 conducts the main scan of the substrate S with the substrate stage 14, the sub scan of the droplet discharge heads H with the carriage 15, the droplet discharge process with the droplet discharge heads H, and the measurement process with the measurement irradiator 17A, and the drying process with the drying irradiator 17B.

The controller 30 stores the converting data TID in the ROM. The converting data TID is, similarly to the first embodiment, data correlating a plurality of various optical constants or a plurality of various liquid thicknesses with light wave information of the drying light Bd based on a target film thickness of the thin film. The controller 30 converts the liquid film data related to the optical constant, or the film shape of the liquid film F0 into data for modulating the drying light Bd by the converting data TID.

When receiving the mode selection signal Im from the input/output device 31, the controller 30 allows the irradiator 17 to selectively conduct the process operation based on the mode selection signal Im, that is, one of the measurement process with the measuring irradiator 17A and the drying process with the drying irradiator 17B.

The controller 30 is coupled to the irradiator driving circuit 36 including a driving circuit 36A for measurement and a driving circuit 36B for drying. The controller 30 outputs the measuring light selection signal Cm for allowing the measuring light source 41a to emit the measuring light Bm. The controller 30 outputs the drying light selection signal Cd for allowing the drying light source 45a to emit the drying light Bd.

When the measurement mode is selected, the driving circuit 36A for measurement operates the emitting portion 41 for measurement in response to the measuring light selection signal Cm from the controller 30. Further, the driving circuit 36A for measurement performs A/D conversion of an output signal from the imaging portion 28, and inputs the reflected light data TD related to the interference fringe of the reflected light Br to the controller 30. The controller 30 generates the liquid film data by converting the reflected light data TD, and calculates the optical constant or the film shape at each of the coordinates on each occasion. At this time, the controller 30 extracts only a phase having a constant amplitude by Fourier transformation using the reflected light data TD, and further generates the liquid film data by adding a random phase to the extracted phase.

When the dry mode is selected, the driving circuit 36B for drying operates the emitting portion 45 for drying in response to the drying light selection signal Cd from the controller 30. The controller 30 reads out the converting data TID stored in the ROM, and then converts the optical constant at each of the coordinates on each occasion into the intensity of the drying light Bd so as to generate the modulation data SC for obtaining the intensity. When receiving the irradiation timing signal LT2, the driving circuit 36B for drying operates the modulating portion 46 for drying based on the modulation data SC from the controller 30, and forms the drying light Bd in intensity distribution corresponding to the liquid film data based on the target film thickness data.

Here, advantageous effects of the second embodiment will be described below.

7. In the second embodiment, the measuring light Bm from the measuring light source 41a is emitted to the liquid film F0 so as to detect the reflected light Br from the liquid film F0, thereby generating the liquid film data related to the optical constant of the liquid film F0. Then, based on the converting data TID indicating a relation between the liquid film data and the light wave information of light, the drying light Bd from the drying light source 45a is modulated corresponding to the liquid film data. The drying light Bd having been modulated is emitted to the liquid film F0 so as to dry the liquid film F0.

Therefore, the drying light Bd to be emitted to the liquid film F0 is modulated based on the optical constant of the liquid film F0. In the film forming method described above, the drying light Bd is modulated based on the optical constant of the liquid film F0, thereby enabling the drying process corresponding to component distribution of the liquid film F0 regardless of the film thickness of the liquid film F0. As a result, the film forming method described above can further improve film thickness controllability of the thin film.

8. Further, a light source for generating the liquid film data and a light source for drying the liquid film F0 are individually formed, enhancing flexibility of a wavelength and an intensity respectively for the measuring light Bm and the drying light Bd. Therefore, the film forming method described above can enhance its application range.

The above-mentioned embodiments may be changed as the following.

In the first embodiment above, the droplet discharge device 10 measures the interference fringe of the reflected light Br so as to obtain the film thickness (liquid thickness) distribution of the liquid film F0, that is, the film shape. However, it is not limited to the above, but the droplet discharge device 10 may obtain the film shape of the liquid film F0 by calculating a reflectance of the reflected light Br.

In the first embodiment above, the droplet discharge device 10 measures the interference fringe of the reflected light Br and converts the reflected light data TD so as to obtain the information related to the film shape of the liquid film F0. However, it is not limited to the above, but the droplet discharge device 10 may obtain the optical constant of the liquid film F0 by measuring the interference fringe of the reflected light Br and converting the reflected light data TD. Such structure enables emission of light corresponding to concentration difference of the film material, for example, emission of light with an intensity corresponding to the concentration of the film material as the drying light Bd regardless of the film thickness of the liquid film F0.

In the first embodiment above, the droplet discharge device 10 has the irradiator 17 that is used as the first irradiator and the second irradiator in common, and obtains the film shape of the liquid film F0 by using light from the light source 25a that is common. However, it is not limited to the above. In the droplet discharge device 10, similarly to the second embodiment, the first irradiator may be specified as the measuring irradiator 17A and the second irradiator may be specified as the drying irradiator 17B so as to have a structure in which the film shape of the liquid film F0 and the optical constant of the liquid film F0 are obtained with light from different light sources. This structure can enhance flexibility of a wavelength and an intensity of the measuring light Bm and the drying light Bd because different light sources are used.

In the embodiments above, the droplet discharge device 10 measures the interference fringe of the reflected light Br so as to obtain the film shape of the liquid film F0. However, it is not limited to the above, but the droplet discharge device 10 may calculate a surface shape of the liquid film F0, that is, a coordinate (surface coordinate) in Z direction of the surface of the liquid film F0 in accordance with intensity distribution of the reflected light Br detected by the imaging portion 28.

An imaging position of the reflected light Br varies depending on the surface shape of the liquid film F0. For example, in a case where the surface shape of the liquid film F0 has an inclination, the imaging position of the reflected light Br is displaced toward a position corresponding to the inclination of the surface shape. Therefore, variation of the imaging position is converted into an angle of the surface, providing the surface shape of the liquid film F0, that is, the surface coordinates. According to this structure, the surface coordinates of the liquid film F0 can be measured based on the intensity distribution of the reflected light Br and can supply light corresponding to the surface shape of the liquid film F0 to the liquid film F0.

In the embodiments above, the droplet discharge device 10 measures the interference fringe of the reflected light Br so as to obtain the film shape of the liquid film F0. However, it is not limited to the above, but the droplet discharge device 10 may include a lifting and lowering mechanism for lifting and lowering the irradiator 17 or the substrate stage 14 along Z direction, and detect a focal distance of the emitting portions 25 and 41 with respect to the surface of the liquid film F0 based on an intensity, which is detected by the imaging portion 28, of the reflected light Br.

In a case where an optical image formed on the surface of the liquid film F0 is defocused, an amount of light of the reflected light Br that is detected by the imaging portion 28 is decreased compared to an optical image that is focused. When conducting the measurement process, the droplet discharge device 10 can lift or lower the irradiator 17 or the substrate stage 14 along Z direction so as to detect a height at which the reflected light Br comes to have a predetermined amount of light when the reflected light Br is focused, that is, a surface coordinate of the liquid film F0. According to this structure, the surface coordinate of the liquid film F0 can be measured based on the focal distance of the reflected light Br and can supply light corresponding to the surface coordinate, that is, the film shape of the liquid film F0, to the liquid film F0.

In the embodiments above, the droplet discharge device 10 obtains the film shape or the optical constant of the liquid film F0 based on the reflected light Br from the liquid film F0. However, it is not limited to the above, but the droplet discharge device 10 may obtain the film shape or the optical constant of the liquid film F0 based on transmission light, scattered light, diffraction light, and the like through the liquid film F0. That is, the droplet discharge device 10 can at least have a structure to obtain the film shape or the optical constant of the liquid film F0 by receiving light from the liquid film F0.

In the embodiments above, the droplet discharge device 10 includes the discharge unit 11 and the dryer unit 12. However, it is not limited to the above, but the droplet discharge device 10 may have such a structure that the droplet discharge heads H and the irradiator 17 are mounted on one carriage 15 so as to be shared by the discharge unit 11 and the dryer unit 12. Alternatively, the droplet discharge device 10 may include only the discharge unit 11. In this case, a drying device including the dryer unit 12 may be separately provided and may conduct the droplet discharge process and the drying process by separate devices.

In the embodiments above, the substrate stage 14 reciprocates between the discharge unit 11 and the dryer unit 12. However, it is not limited to the above, for example, the droplet discharge device 10 may have a structure in which the substrate stage 14 is provided to each of the discharge unit 11 and the dryer unit 12 so as to allow a substrate to transfer between the substrate stages 14.

In the embodiments above, the irradiator 17 measures the intensity of the reflected light Br by an interference method. However, that is not limited to the above, the irradiator 17 may detect polarization variation (e.g. a phase difference or an amplitude difference) between the measuring light Bm and the reflected light Br so as to calculate an optical constant (reflectance, refractive index, extinction coefficient, or the like) related to the film thickness of the thin film, that is, the irradiator 17 may employ ellipsometry.

The number of the nozzle row is one in the embodiment, but it may be two ore more.

The droplet discharge device 10 conducts a film forming process employing a single scan method in the embodiments above, however, the device 10 may conduct a film forming process employing a multi-scan method.

In the embodiments above, the droplet discharge device 10 modulates the intensity of the drying light Bd corresponding to the liquid film data. However, it is not limited to the above, but the droplet discharge device 10 may modulate a wavelength of the drying light Bd corresponding to the liquid film data.

In the embodiments above, the droplet discharge device 10 converts the light energy of the Bd into thermal energy so as to adjust the drying speed distribution of the liquid film F0, thereby controlling the film thickness distribution of the liquid film. However, it is not limited to the above, but the droplet discharge device 10 may flow the ink Ik by using the light energy of the drying light Bd so as to control the film thickness distribution of the liquid film F0. That is, the droplet discharge device 10 may locally evaporate the ink Ik by light pressure of the drying light Bd or the drying light Bd itself so as to control the film thickness distribution of the liquid film F0.

The entire disclosure of Japanese Patent Application Nos: 2007-212649, filed Aug. 17, 2007 and 2008-182379, filed Jul. 14, 2008 are expressly incorporated by reference herein.

What is claimed is:

1. A film-forming method, comprising:
a) discharging a liquid including a film material on an object so as to form a liquid film made of the liquid;
b) measuring distribution of an optical constant related to a film thickness of a thin film by irradiating the liquid film with light from a first light source so as to detect light from the liquid film; and
c) modulating light from a second light source corresponding to the optical constant of the liquid film based on converting data indicating a relation between the optical constant and light wave information of the light from the second light source while irradiating the liquid film with the light from the second light source so as to dry the liquid film to form the thin film on the object.

2. The film-forming method according to claim 1, wherein the converting data correlates the optical constant in a case where a concentration of the film material is high with light with a low intensity, and step c) includes modulating an intensity of the light from the second light source corresponding to a measurement result of the light from the liquid film based on the converting data so as to dry the liquid film.

3. The film-forming method according to claim 1, wherein the converting data correlates the optical constant in a case where a concentration of the film material is low with light with a high intensity, and step c) includes modulating an intensity of the light from the second light source corresponding to a measurement result of the light from the liquid film based on the converting data so as to dry the liquid film.

4. A film-forming method, comprising:
d) discharging a liquid including a film material on an object so as to form a liquid film made of the liquid;
e) measuring a film shape of the liquid film by irradiating the liquid film with light from a first light source so as to detect light from the liquid film; and
f) modulating light from a second light source corresponding to the film shape of the liquid film based on converting data indicating a relation between the film shape and light wave information of the light from the second light source while irradiating the liquid film with the light from the second light source so as to dry the liquid film to form the thin film on the object.

5. The film-forming method according to claim 4, wherein step e) includes detecting a position of the light from the liquid film by irradiating the liquid film with the light from the first light source so as to measure the film shape of the liquid film based on a detecting result of the position.

6. The film-forming method according to claim 4, wherein step e) includes detecting a focal distance of the first light source with respect to the liquid film by irradiating the liquid film with the light from the first light source so as to measure the film shape of the liquid film based on a detecting result of the focal distance.

7. The film-forming method according to claim 4, wherein step e) includes imaging interference light of the liquid film by irradiating the liquid film with the light from the first light source so as to measure the film shape of the liquid film based on an imaging result of the interference light.

8. The film-forming method according to claim 4, wherein the converting data correlates a thick part of the liquid film with light with a low intensity, and step f) includes modulating an intensity of the light from the second light source corresponding to a measurement result of the light from the liquid film based on the converting data so as to dry the liquid film.

9. The film-forming method according to claim 4, wherein the converting data correlates a thin part of the liquid film with light with a high intensity, and step f) includes modulating an intensity of the light from the second light source corresponding to a measurement result of the light from the liquid film based on the converting data so as to dry the liquid film.

10. The film-forming method according to claim 1, wherein step b) includes imaging interference light of the liquid film by irradiating the liquid film with the light from the first light source while step c) includes modulating the light from the second light source based on only a phase of the interference light.

11. The film-forming method according to claim 10, wherein step c) includes modulating the light from the second light source based on data in which a random phase is added to the phase of the interference light.

12. The film-forming method according to claim 1, wherein the light from the second light source has a wavelength at which the light is absorbed by the object at a higher rate than a rate at which the light is absorbed by the liquid.

13. The film-forming method according to claim 1, wherein step b) and step c) are alternately repeated.

14. The film-forming method according to claim 1, wherein the first light source and the second light source are served by a single light source.

15. A film-forming device, comprising:
a discharge head discharging a liquid including a film material on an object so as to form a liquid film on the object;
a dryer drying the liquid film so as to form a thin film on the object, the dryer including:
a first light source;
a second light source;
a first irradiator irradiating the liquid film with light from the first light source;
a detector detecting light from the liquid film so as to measure an optical constant related to a thickness of the thin film;
a modulator modulating light from the second light source; and
a second irradiator irradiating the liquid film with light from the modulator; and
a controller controlling the discharge head and the dryer, the controller including:
a mode selector selecting a measurement mode and a dry mode; and
a memory storing converting data indicating a relation between the optical constant and light wave information of the light from the second light source, wherein the controller operates the first irradiator and the detector so as to measure the optical constant related to the thickness of the thin film in the measurement mode, while the controller generates modulating data for modulating the light from the second light source based on the optical constant of the liquid film and the converting data, and outputs light corresponding to the modulating data to the liquid film by operating the modulator with the modulating data in the dry mode.

16. The film-forming device according to claim 15, wherein the converting data correlates the optical constant in a case where a concentration of the film material is high with light with a low intensity, and the controller modulates the light from the second light source based on the converting data in the dry mode.

17. The film-forming device according to claim 15, wherein the converting data correlates the optical constant in a case where a concentration of the film material is low with light with a high intensity, and the controller modulates the light from the second light source based on the converting data in the dry mode.

18. A film-forming device, comprising:
a discharge head discharging a liquid including a film material on an object so as to form a liquid film on the object;
a dryer drying the liquid film so as to form a thin film on the object, the dryer including:
a first light source;
a second light source;
a first irradiator irradiating the liquid film with light from the first light source;
a detector detecting light from the liquid film so as to measure a film shape of the liquid film;
a modulator modulating light from the second light source; and
a second irradiator irradiating the liquid film with light from the modulator; and
a controller controlling the discharge head and the dryer, the controller including:
a mode selector selecting a measurement mode and a dry mode;
a memory storing converting data indicating a relation between the film shape and light wave information of the light from the second light source, wherein the controller operates the first irradiator and the detector so as to generate information on the film shape of the liquid film in the measurement mode, while the controller generates modulating data for modulating the light from the second light source based on the film shape of the liquid film and the converting data, and outputs light corresponding to the modulating data to the liquid film by operating the modulator with the modulating data.

19. The film-forming device according to claim 18, the controller calculates a surface coordinate of the liquid film as information on the film shape based on a detecting result from the detector in the measurement mode.

20. The film-forming device according to claim 18, the detector detects a position of the light from the liquid film, while the controller calculates a surface coordinate of the liquid film as information on the film shape based on the position of the light from the liquid film, the position being detected by the detector, in the measurement mode.

21. The film-forming device according to claim 18, the detector detects a focal position of the first light source with respect to the liquid film, while the controller calculates a surface coordinate of the liquid film as information on the film shape based on the focal position detected by the detector in the measurement mode.

22. The film-forming device according to claim 18, the detector detects interference light of the liquid film, while the controller calculates a surface coordinate of the liquid film as information on the film shape based on the interference light detected by the detector.

23. The film-forming device according to claim 18, wherein the converting data correlates a thick part of the liquid film with light with a low intensity.

24. The film-forming device according to claim 18, wherein the converting data correlates a thin part of the liquid film with light with a high intensity.

25. The film-forming device according to claim 15, wherein the detector images interference light of the liquid film, while the controller modulates the light from the second light source based on only a phase of the interference light in the dry mode.

26. The film-forming device according to claim 25, wherein the controller modulates the light from the second light source based on data in which a random phase is added to the phase of the interference light.

27. The film-forming device according to claim 15, wherein the first light source and the second light source are served by a single light source.
